(19) United States
(12) Patent Application Publication
(10) Pub. No.: US 2025/0113574 A1
(43) Pub. Date: Apr. 3, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ming-Che CHEN, Hsinchu City (TW); Yen-Cheng LAI, Tainan City (TW); Pin-Jung CHEN, Hsinchu City (TW); Ming-Heng TSAI, Taipei (TW); Feng-Ming CHANG, Taitung City (TW); Chun-Jun LIN, Hsinchu City (TW)

(73) Assignee: Taiwan Semiconductor Manufacturing Company, Ltd., Hsinchu (TW)

(21) Appl. No.: 18/478,071

(22) Filed: Sep. 29, 2023

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/021; H10D 84/0133; H10D 84/0135; H10D 84/0147; H10D 84/038; H10D 84/83

(57) ABSTRACT

A method of forming a semiconductor structure, includes forming a fin structure over a substrate in a Z-direction; forming a dummy gate structure extending in a Y-direction and over the fin structure; and forming gate spacers on sidewalls of the dummy gate structure. The fin structure includes first semiconductor layers and second semiconductor layers alternately stacked. The method further includes removing a portion of the dummy gate structure to form a first trench that exposes upper portions of the gate spacers; forming an insulating material in the first trench; partially removing the insulating material to form insulating layers on sidewalls of the upper portions of the gate spacers; removing a remaining portion of the dummy gate structure to expose lower portions of the gate spacers; and partially etching the lower portions of the gate spacers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 and FIG. 2 are perspective views of a workpiece at various fabrication stages, in accordance with some embodiments of the present disclosure.

FIGS. 3A, 4A, 5A, 6A, 7A, 8A, 9A, 10A, 11A, 12A, 13A, 14A, 15A, 16A, and 17A are X-Z cross-sectional views of the workpiece at various fabrication stages along a line A-A′ of FIG. 2, in accordance with some embodiments of the present disclosure.

FIGS. 3B, 4B, 5B, 6B, 7B, 8B, 9B, 10B, 11B, 12B, 13B, 14B, 15B, 16B, and 17B are Y-Z cross-sectional views of the workpiece at various fabrication stages along a line B-B′ of FIG. 2, in accordance with some embodiments of the present disclosure.

FIGS. 18A and 18B are Y-Z cross-sectional views of the workpiece at various fabrication stages along a line B-B′ of FIG. 2, in accordance with some embodiments of the present disclosure.

FIGS. 19A, 20A, 21A, 22A, 23A, 24A, 25A, and 26A are X-Z cross-sectional views of the workpiece at various fabrication stages along a line A-A′ of FIG. 2, in accordance with some alternative embodiments of the present disclosure.

FIGS. 19B, 20B, 21B, 22B, 23B, 24B, 25B, and 26B are Y-Z cross-sectional views of the workpiece at various fabrication stages along a line B-B′ of FIG. 2, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor.

During the formation of semiconductor structure (e.g., GAA transistor), removal processes, such as poly removal process, sidewall trimming process, sheet formation process, and sheet trimming process, will lead to sidewall loss of gate spacers. Which causes an undesired funnel profile of the outer gate structure (i.e., the portion of the gate structure over the topmost nanostructure). The undesired funnel profile results the gate structure with a wider upper portion that is closer to the contacts nearby. Which decreases the process window of the contacts nearby (i.e., the gate structure is more likely to contact the conductive material of the contacts nearby during the deposition of the contacts nearby and cause a short circuit), and increases the leakage between the gate structure and the contacts nearby (i.e., the gate structure and the contacts nearby are too close).

The present disclosure provides embodiments of methods and structures with insulating layers formed between the upper portions of the gate spacers and the upper portion of the gate structure. The insulating layers is formed on sidewalls of the upper portions of the gate spacers during the removal of the dummy gate structure. The insulating layers can protect the upper portions of the gate spacers from being removed during subsequent manufacturing processes (e.g. etching processes), and thus the sidewalls of the gate structure can keep straight and the critical dimension of the upper portion of the gate structure can be maintained smaller instead of being enlarged to have a funnel profile. Therefore, the process window of the contacts nearby can be increased and the leakage between the gate structure and the contacts nearby can be decreased. Furthermore, the present disclosure also provides embodiments that combine the formation of insulating layers and the sidewall trimming process of gate spacers. The process can modulate the critical dimensions of the upper portion and the lower portion of the gate structures independently to satisfy various design requirements.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise excepted or described.

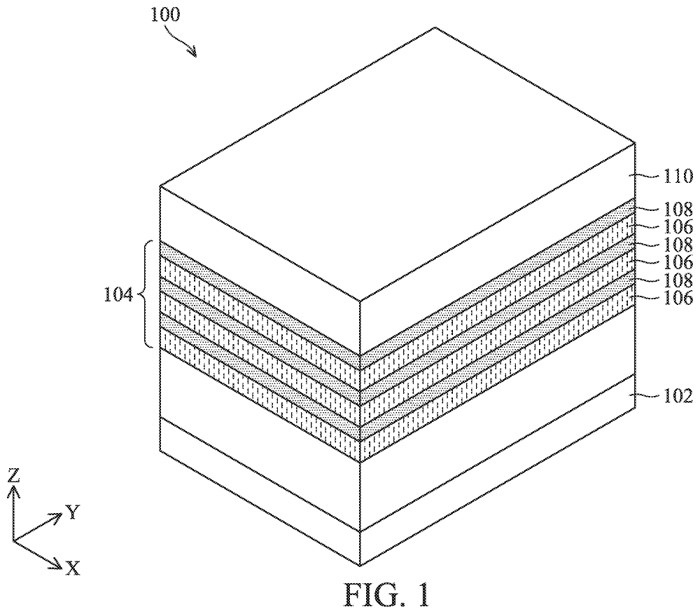

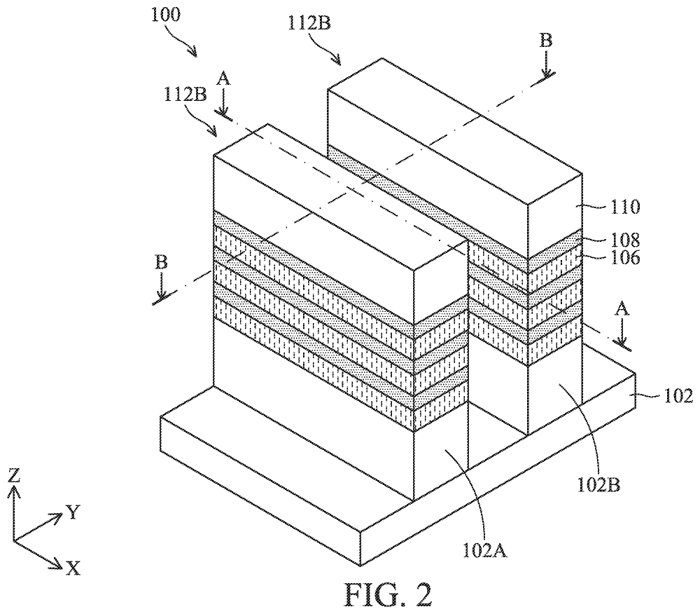

FIG. 1 and FIG. 2 are perspective views of a workpiece 100 at various fabrication stages, in accordance with some embodiments of the present disclosure. Referring to FIG. 1, a workpiece 100 is provided in accordance with some embodiments. As shown in FIG. 1, the workpiece 100 includes a substrate 102 and a stack 104 over the substrate 102, in accordance with some embodiments. In some embodiments, the substrate 102 contains a semiconductor material, such as bulk silicon (Si). In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B)). The n-type and p-type well regions may be formed by using ion implantation or thermal diffusion. In some embodiments, the n-type well regions have an n-type dopant concentration of about 5×10¹⁶ cm⁻³ to about 5×10¹⁹ cm⁻³, and the p-type well regions have a p-type dopant concentration of about 5×10¹⁶ cm⁻³ to about 5×10¹⁹ cm⁻³. Since the workpiece 100 will be fabricated into a semiconductor structure 100 upon conclusion of the fabrication processes, the workpiece 100 may be referred to as the semiconductor structure 100 as the context requires.

The stack 104 may include semiconductor layers 106 and semiconductor layers 108. In some embodiments, the semiconductor layers 106 and the semiconductor layers 108 are alternatingly stacked in the Z-direction. The semiconductor layers 106 and the semiconductor layers 108 may have different semiconductor compositions. In some embodiments, the semiconductor layers 106 are formed of silicon germanium (SiGe), and the semiconductor layers 108 are formed of silicon (Si). In these embodiments, the additional germanium content in the semiconductor layers 106 allows selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over (on) the substrate 102 using an epitaxial growth process such as metalorganic chemical vapor deposition (MOCVD), vapor-phase epitaxy (VPE), and molecular beam epitaxy (MBE), although other deposition processes, such as chemical vapor deposition (CVD), low pressure CVD (LPCVD), atomic layer deposition (ALD), ultrahigh vacuum CVD (UHVCVD), remote plasma CVD (RPCVD), combinations thereof, or the like, may also be utilized. The semiconductor layers 106 and the semiconductor layers 108 are deposited alternatingly, one-after-another, to form the stack 104. It should be noted that, three (3) layers of the semiconductor layers 106 and three (3) layers of the semiconductor layers 108 are alternately and vertically arranged (or stacked) as shown in FIG. 1, which are for illustrative purposes only and are not intended to be limiting beyond what is specifically recited in the claims. The number of layers depends on the desired number of channels members for the semiconductor device. In some embodiments, there may be from 2 to 10 semiconductor layers 106 alternating with 2 to 10 semiconductor layers 108 in the stack 104.

For patterning purposes, the workpiece 100 may also include a hard mask layer 110 over the stack 104. The hard mask layer 110 may be a single layer structure or a multi-layer structure. In some embodiments, the hard mask layer 110 is a single layer structure and includes a silicon germanium layer. In some embodiments, the hard mask layer 110 is a multi-layer structure and includes a silicon nitride layer and a silicon oxide layer over the silicon nitride layer. In other embodiments, the hard mask layer 110 is a multi-layer structure and includes a silicon germanium layer and a silicon layer over the silicon germanium layer.

Referring to FIG. 2, the substrate 102, the stack 104, and the hard mask layer 110 are then patterned to form a fin structure 112A and a fin structure 112B (may be collectively referred to as fin structures 112) over the substrate 102, in accordance with some embodiments. In some embodiments, each of the fin structures 112 includes a base portion (base fins 102A and 102B) formed from a portion of the substrate 102 and a stack portion formed from the stack 104 over the base portion, as shown in FIG. 2. The stack portion includes the semiconductor layers 106 and the semiconductor layers 108 alternately stacked over the substrate 102. In some embodiments, the base fins 102A and 102B protrude from the substrate 102. Each of the fin structures 112 extends lengthwise in the X-direction and extends vertically in the Z-direction over the substrate 102, and arranged in the Y-direction. In some embodiments, widths of the fin structures 112 along the Y-direction are the same. Although the two fin structures 112A and 112B are formed and shown herein, more fin structures may be formed, such as three or more fin structures.

The fin structures 112 may be patterned using suitable processes including photolithography processes and etching processes. The suitable processes may include double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fin structures 112 by etching the stack 104 and the substrate 102. The etching process may include dry etching, wet etching, reactive ion etching (RIE), and/or other suitable processes. In some embodiments, the lithography processes include photoresist coating (e.g., spin-on coating), soft baking, mask aligning, exposure, post-exposure baking, developing the photoresist, rinsing, and drying (e.g., hard baking). In some other embodiments, the photolithography processes may be implemented or replaced by other suitable methods, such as maskless photolithography, electron-beam (e-beam) writing, and ion-beam writing.

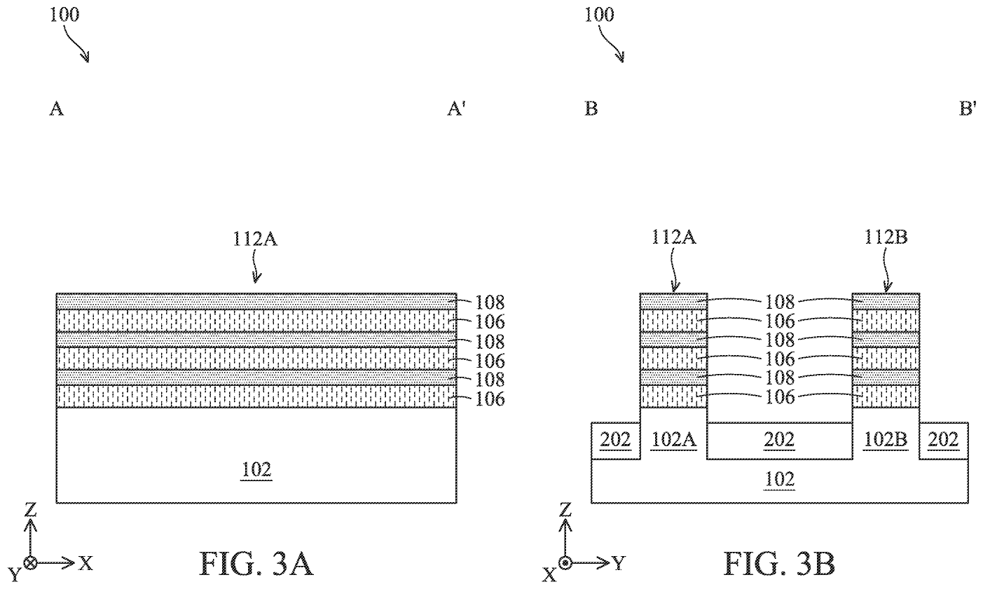

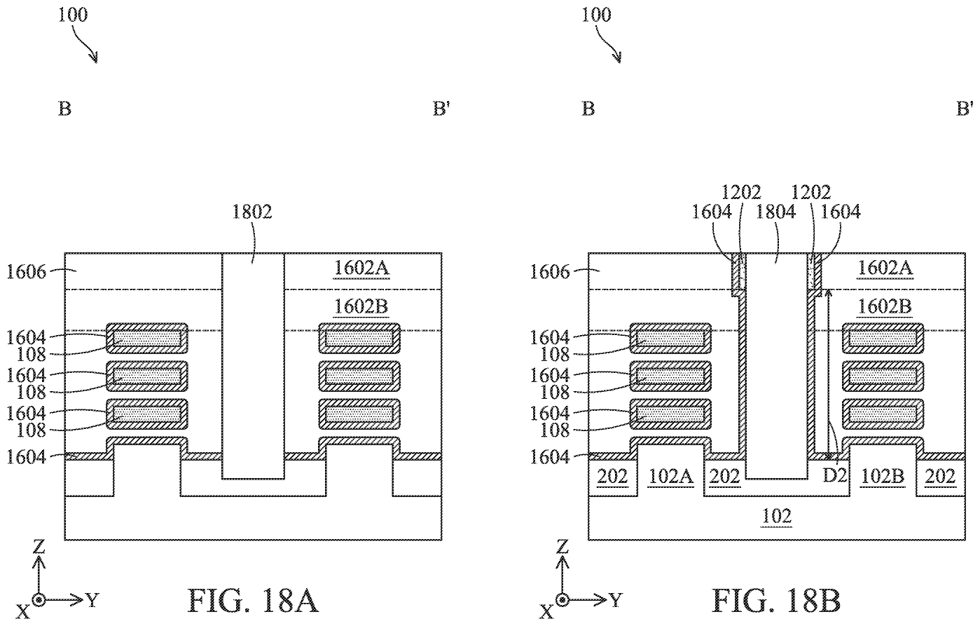

FIGS. 3A to 17A are X-Z cross-sectional views of the workpiece 100 at various fabrication stages along a line A-A′ of FIG. 2, in accordance with some embodiments of the present disclosure. FIGS. 3B to 17B are Y-Z cross-sectional views of the workpiece 100 at various fabrication stages along a line B-B′ of FIG. 2, in accordance with some embodiments of the present disclosure. FIGS. 18A and 18B are Y-Z cross-sectional views of the workpiece 100 at various fabrication stages along a line B-B′ of FIG. 2, in accordance with some embodiments of the present disclosure.

Referring to FIGS. 3A and 3B, an isolation structure 202 is formed, in accordance with some embodiments. After the fin structures 112 are formed, the hard mask layer 110 over the fin structures 112 is removed and the isolation structure 202 is formed over the substrate 102. In some embodiments, the isolation structure 202 is formed between the fin structures 112. In other embodiments, the isolation structure 202 is formed around the fin structures 112. More specifically, the isolation structure 202 is formed between and around the base fins (e.g., base fins 102A and 102B) of the fin structures 112. The isolation structure 202 may also be referred to as shallow trench isolation (STI) feature.

In some embodiments, a dielectric material for the isolation structure 202 is first deposited over the workpiece 100. Specifically, the dielectric material is deposited and formed over the fin structures 112 and the substrate 102 to cover the fin structures 112 and the substrate 102. In some embodiments, the dielectric material is formed to wrap around the fin structures 112. In some embodiments, the dielectric material may include silicon oxide, silicon nitride, silicon oxynitride, fluorine-doped silicate glass (FSG), a low-k dielectric material, combinations thereof, and/or other suitable materials. In various embodiments, the dielectric material may be deposited using a deposition process, such as a CVD, a subatmospheric CVD (SACVD), a flowable CVD (FCVD), an ALD, spin-on coating, and/or other suitable process. The deposited dielectric material is then thinned and planarized, for example by a chemical mechanical polishing (CMP) process, until top surfaces of the hard mask layer 110 is exposed (not shown). The planarized dielectric material is further recessed by a dry etching process, a wet etching process, and/or a combination thereof to form the isolation structure 202. In some embodiments, the stack portions of the fin structures 112 rise above the isolation structures 202 while the base fins 102A and 102B are surrounded by the isolation structures 202, as shown in FIG. 3B. In other words, top surfaces (or topmost surfaces) of the substrate 102 are higher than the top surface of the isolation structure 202. In some embodiments, before the formation of the isolation structure 202, a liner layer may be conformally deposited over the substrate 102 using a deposition process, such as CVD, ALD, high-density plasma CVD (HDPCVD), MOCVD, RPCVD, plasma-enhanced CVD (PECVD), LPCVD, atomic layer CVD (ALCVD), atmospheric pressure CVD (APCVD), FCVD, or combinations thereof.

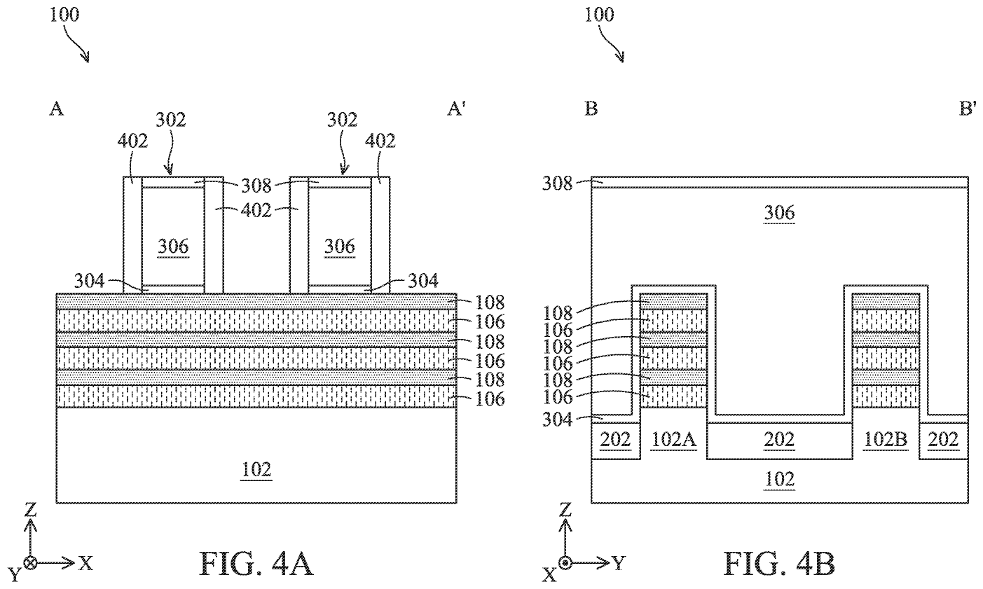

Referring to FIGS. 4A and 4B, dummy gate structures 302 may be formed over the fin structures 112 and over the isolation structure 202, in accordance with some embodiments. In some embodiments, the dummy gate structures 302 may be configured to extend lengthwise in the Y-direction and wrap around top surfaces and side surfaces of the fin structures 112, as shown in FIG. 4B. In some embodiments, in order to form the dummy gate structures 302, a dummy gate dielectric material for dummy gate dielectric layers 304 is first formed over the fin structures 112 and over the isolation structure 202. More specifically, in some embodiments, the dummy gate dielectric material is conformally formed on the sidewalls of the fin structures 112 and over the top surfaces of the fin structures 112 and the isolation structure 202, as shown in FIG. 4B. In some embodiments, the dummy gate dielectric layer 304 may include, for example, a dielectric material such as a nitride (e.g., silicon nitride, silicon oxynitride), a carbide (e.g., silicon carbide), an oxide (e.g., silicon oxide), or some other suitable materials.

Then, in some embodiments, a dummy gate electrode material for dummy gate electrode layers 306 is formed over the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, hard mask layers 308 are formed over the dummy gate electrode material. In some embodiments, the hard mask layers 308 may be formed by using photolithography and removal (e.g., etching) processes. In some embodiments, the hard mask layers 308 may include photoresist materials or hard mask materials. In some embodiments, each of the hard mask layers 308 may include multiple layers, such as a silicon nitride layer and a silicon oxide layer. After the formation of the hard mask layers 308, a removal process (e.g., etching) may be performed to remove portions of the dummy gate electrode material for the dummy gate electrode layers 306 and the dummy gate dielectric material for the dummy gate dielectric layers 304 that are not directly underlie the hard mask layers 308, thereby forming the dummy gate structures 302. Each of the dummy gate structures 302 has the dummy gate dielectric layer 304, the dummy gate electrode layer 306, and the hard mask layer 308. The dummy gate dielectric layers 304 may also be referred to as dummy interfacial layers.

The dummy gate structures 302 may undergo a gate replacement process through subsequent processing to form metal gates, such as a high-k metal gate, as discussed in greater detail below. FIG. 4A shows two dummy gate structures 302. In some embodiments, less or more dummy gate structures may be formed for one or more transistors sharing source/drain regions.

Still referring to FIGS. 4A and 4B, after the formation of the dummy gate structures 302, gate spacers 402 are formed on sidewalls of the dummy gate structures 302 and over the top surfaces of the fin structures 112, in accordance with some embodiments. More specifically, in some embodiments, the gate spacers 402 are formed on the opposite sidewalls of the dummy gate structures 302, and over the top surface of the topmost one of the semiconductor layers 108, as shown in FIG. 4A. The gate spacers 402 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. In some embodiments, the gate spacers 402 include a low-k dielectric material, such as those described herein. The gate spacers 402 may include a single layer or a multi-layer structure.

In some embodiments, the gate spacers 402 may be formed by conformally depositing a spacer layer (containing the dielectric material) over the fin structures 112 and the dummy gate structures 302. Then, an anisotropic etching process is performed to remove top portions of the spacer layer from the top surfaces of the fin structures 112 and the dummy gate structures 302. After the anisotropic etching process, the portions of the spacer layer on the sidewall surfaces of the fin structures 112 and the dummy gate structures 302 substantially remain and become the gate spacers 402. In some embodiments, the anisotropic etching process is a dry (e.g., plasma) etching process. Additionally or alternatively, the formation of the gate spacers 402 may also involve chemical oxidation, thermal oxidation, CVD, PVD, ALD, HDPCVD, MOCVD, RPCVD, PECVD, LPCVD, ALCVD, APCVD, FCVD, and/or other suitable methods. The gate spacers 402 may also be interchangeably referred to as top spacers.

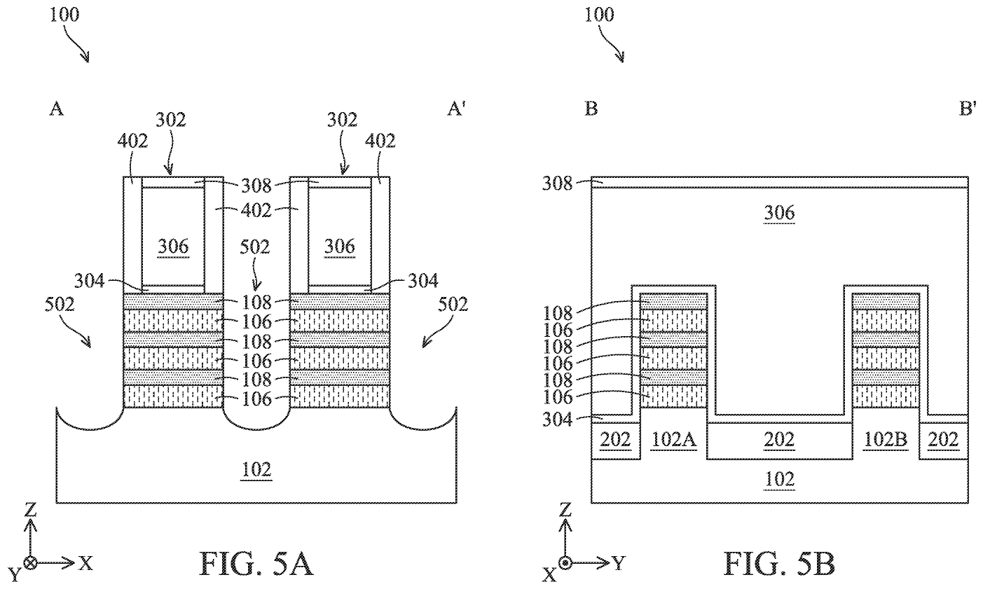

Referring to FIGS. 5A and 5B, the fin structures 112 are recessed to form source/drain trenches 502 in the fin structures 112 (or passing through semiconductor layers 106 and 108) for source/drain regions, in accordance with some embodiments. The source/drain trenches 502 are formed on opposite sides of the dummy gate structures 302. Specifically, the source/drain trenches 502 may be formed by performing one or more etching processes to remove portions of the semiconductor layers 106, the semiconductor layers 108, and the substrate 102 (e.g., base fins 102A and 102B) that do not vertically overlap or not be covered by the dummy gate structures 302 and the gate spacers 402. In some embodiments, a single etchant may be used to remove the semiconductor layers 106, the semiconductor layers 108, and the substrate 102. In other embodiments, multiple etchants may be used to perform the etching process. In some embodiments, portions of the substrate 102 are etched, so that the source/drain trenches 502 extend into the substrate and each has a concave surface in the substrate 102, as shown in FIG. 5A.

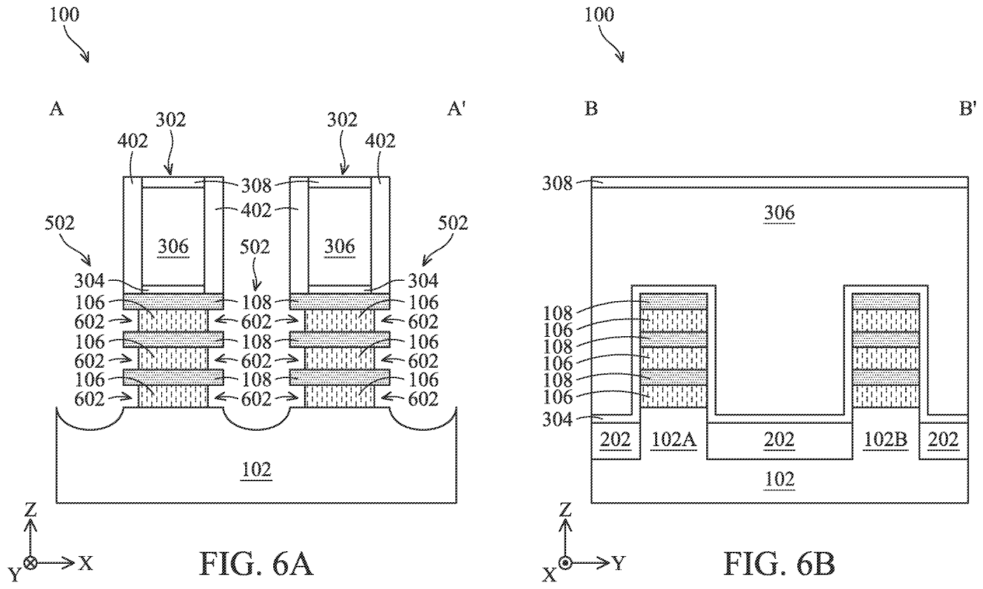

Referring to FIGS. 6A and 6B, the semiconductor layers 106 exposed in the source/drain trenches 502 are partially recessed by a selective etching process, in accordance with some embodiments. Specifically, the selective etching process is performed that selectively etches the side portions of the semiconductor layers 106 below the gate spacers 402 through the source/drain trenches 502, with minimal etching (or substantially no etching) of semiconductor layers 108. After the selective etching process, inner spacer recesses 602 are formed between the semiconductor layers 108 as well as between the semiconductor layers 108 and the substrate 102, below the gate spacers 402. The selective etching process is configured to laterally etch (e.g., along the X-direction) the semiconductor layers 106 below the gate spacers 402. The selective etching process may be a dry etching process, a wet etching process, other suitable etching process, or combinations thereof.

In some embodiments, the semiconductor layers 108 are also etched during the selective etching process, and the inner spacer recesses 602 partially extend in the Z-direction into the semiconductor layers 108. In some embodiments, the semiconductor layers 108 include curved top surfaces and curved bottom surface exposed by the inner spacer recesses 602.

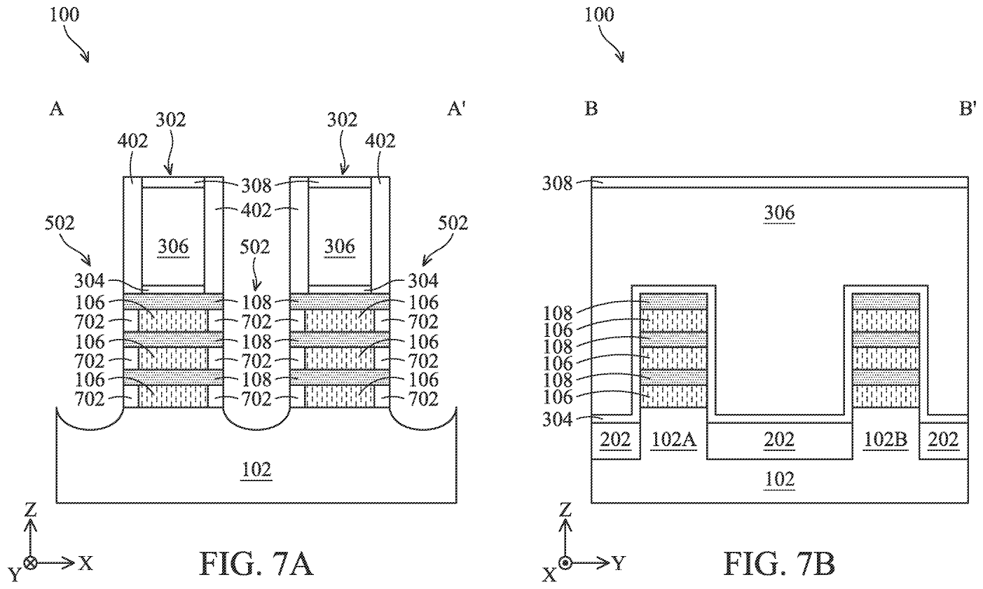

Referring to FIGS. 7A and 7B, inner spacers 702 are formed in the inner spacer recesses 602 to fill the inner spacer recesses 602, in accordance with some embodiments. In some embodiments, sidewalls of the inner spacers 702 are aligned to the sidewalls of the gate spacers 402 and the semiconductor layers 108. In some other embodiments, sidewalls of the inner spacers 702 have concave surfaces exposed by the source/drain trenches 502.

In order to form the inner spacers 702, a deposition process is performed to form a spacer layer into the source/drain trenches 502 and the inner spacer recesses 602. For example, the deposition process may be CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 502. The deposition process is configured to ensure that the spacer layer fills the inner spacer recesses 602 between the semiconductor layers 108 as well as between the semiconductor layer 108 and the substrate 102 under the gate spacers 402. An etching process is then performed that selectively etches the spacer layer to form inner spacers 702 (as shown in FIG. 7A) with minimal etching (or substantially no etching) of the semiconductor layer 108, the substrate 102, the dummy gate structures 302, and the gate spacers 402.

The spacer layer (and thus the inner spacers 702) may include a material that is different than the material of the semiconductor layers 108 and the material of the gate spacers 402 to achieve desired etching selectivity during the etching process. In some embodiments, the inner spacers 702 include a dielectric material that includes silicon, oxygen, carbon, nitrogen, other suitable material, or combinations thereof (for example, silicon oxide (SiO₂), silicon oxynitride (SiON), silicon oxycarbide (SiOC), silicon oxycarbon nitride (SiOCN)). In some embodiments, the inner spacers 702 include a low-k dielectric material (e.g., the material has a dielectric constant that is less than a dielectric constant of silicon dioxide (e.g., k<3.9)). For example, the low-k dielectric material may include Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other suitable dielectric material, or combinations thereof. In some embodiments, the inner spacers 702 include a dielectric material having a dielectric constant that is less than about 2.5 (i.e., an extreme low-k (ELK) dielectric material). For example, the ELK dielectric material may include SiO₂ (e.g., porous silicon dioxide), silicon carbide (SiC), and/or carbon-doped oxide (e.g., a SiCOH-based material (having, for example, Si-CH₃ bonds)), each of which is tuned/configured to exhibit a dielectric constant less than about 2.5.

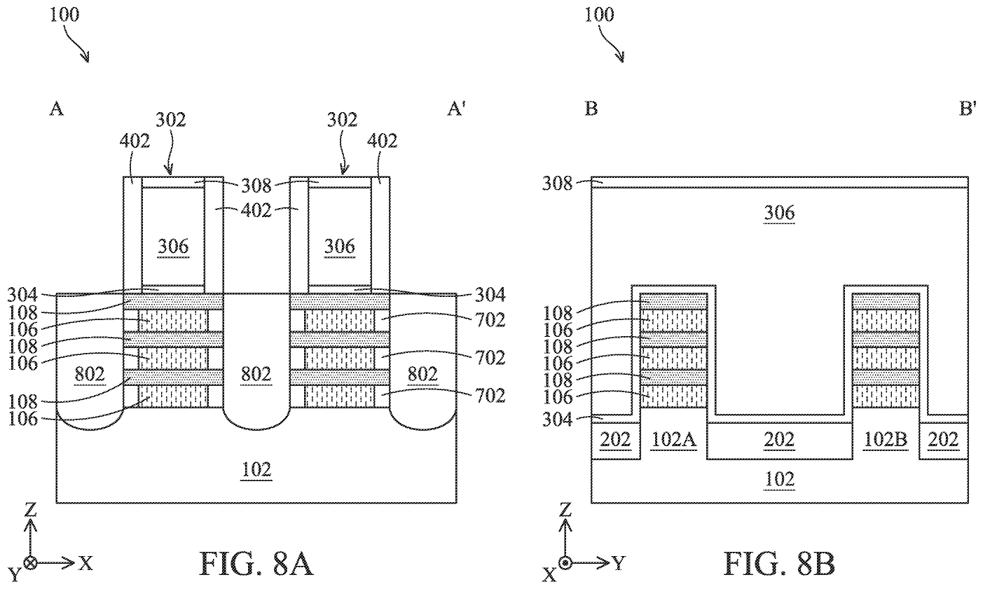

Referring to FIGS. 8A and 8B, source/drain features 802 are formed in the source/drain trenches 502, in accordance with some embodiments. The source/drain features 802 pass through the semiconductor layers 108 and are in the fin structures 112. The source/drain features 802 are also formed on opposite sides of the dummy gate structures 302 in the X-direction. In some embodiments, the source/drain features 802 are connected to and in contact with the semiconductor layers 108. That is, the source/drain features 802 are attached to opposite sides of the semiconductor layers 108. In some embodiments, the semiconductor layers 108 serve as channels to connect one source/drain feature 802 to another source/drain feature 802. Therefore, the semiconductor layers 108 may also be referred to as channels, channel layers, or channel members. In some embodiments, the top surfaces of the source/drain features 802 are substantially level with the top surfaces of the topmost semiconductor layers 108 (i.e., substantially coplanar). In other embodiments, the source/drain features 802 may have top surfaces that extend higher than the top surfaces of the topmost semiconductor layers 108 (e.g., in the Z-direction).

One or more epitaxy processes may be employed to grow the source/drain features 802. Epitaxy processes can implement CVD deposition techniques (e.g., vapor-phase epitaxy (VPE), MOCVD, UHVCVD, LPCVD, and/or PECVD), MBE, other suitable selective epitaxial growth (SEG) processes, or combinations thereof. The source/drain features 802 may include any suitable semiconductor materials. For example, the source/drain features 802 for n-type GAA transistors may include silicon (Si), silicon carbide (SiC), silicon phosphide (SiP), silicon arsenide (SiAs), silicon phosphoric carbide (SiPC), or combinations thereof. For example, the source/drain features 802 for p-type GAA transistors may include silicon (Si), silicon germanium (SiGe), germanium (Ge), silicon germanium carbide (SiGeC), or combinations thereof.

The source/drain features 802 may be doped in-situ or ex-situ. For example, the epitaxially grown Si source/drain features may be doped with carbon to form silicon:carbon (Si:C) source/drain features, phosphorous to form silicon:phosphor (Si:P) source/drain features, or both carbon and phosphorous to form silicon carbon phosphor (SiCP) source/drain features; and the epitaxially grown SiGe source/drain features may be doped with boron. In some embodiments, one or more annealing processes may be performed to activate the dopants in the source/drain features 802. The annealing processes may include rapid thermal annealing (RTA) and/or laser annealing processes.

The source/drain features 802 may also be referred to as source/drain, or source/drain regions. In some embodiments, source/drain feature(s) 802 may refer to a source or a drain, individually or collectively dependent upon the context. In some embodiments, the source/drain features 802 for n-type transistors may be referred to as n-type source/drain features and the source/drain features 802 for p-type transistors may be referred to as p-type source/drain features.

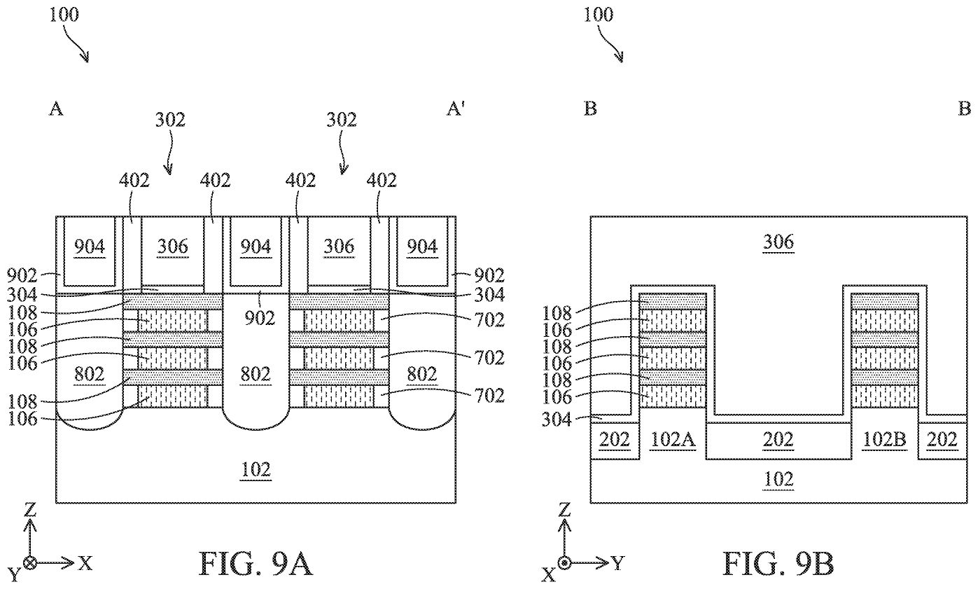

Referring to FIGS. 9A and 9B, a contact etch stop layer (CESL) 902 over the source/drain features 802 and an interlayer dielectric (ILD) layer 904 over the CESL 902 are formed to fill the space between the gate spacers 402, in accordance with some embodiments. Specifically, in some embodiments, the CESL 902 is conformally formed on the sidewalls of the gate spacers 402 and over the top surfaces of the source/drain features 802, as shown in FIG. 9A. The ILD layer 904 is formed over and between the CESL 902 to fill the space between the CESL 902 or between the gate spacers 402.

The CESL 902 may include a material that is different than ILD layer 904. The CESL 902 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESL 902 may be formed by CVD, PVD, ALD, HDPCVD, MOCVD, RPCVD, PECVD, LPCVD, ALCVD, APCVD, FCVD, or other suitable methods. The ILD layer 904 may include tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 904 may be formed by CVD, PVD, ALD, HDPCVD, MOCVD, RPCVD, PECVD, LPCVD, ALCVD, APCVD, FCVD, or other suitable methods.

Subsequent to the deposition of the CESL 902 and the ILD layer 904, a CMP process and/or other planarization process is performed on the CESL 902, the ILD layer 904, the gate spacers 402, and the hard mask layers 308 until the top surfaces of the dummy gate electrode layers 306 are exposed. In some embodiments, portions of the dummy gate electrode layers 306 are removed after the planarization process. In some embodiments, the ILD layer 904 is recessed to a level below the top surfaces of the dummy gate electrode layers 306, and then an ILD protection layer (not shown) is formed over the ILD layer 904 to protect the ILD layer 904 from subsequent etching processes. As such, the ILD layer 904 is surrounded by the CESL 902 and the ILD protection layer. In some embodiments, the ILD protection layer includes a material that is the same as or similar to that in the CESL 902. In some other embodiments, the ILD protection layer includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, HDPCVD, MOCVD, RPCVD, PECVD, LPCVD, ALCVD, APCVD, FCVD, or other suitable methods.

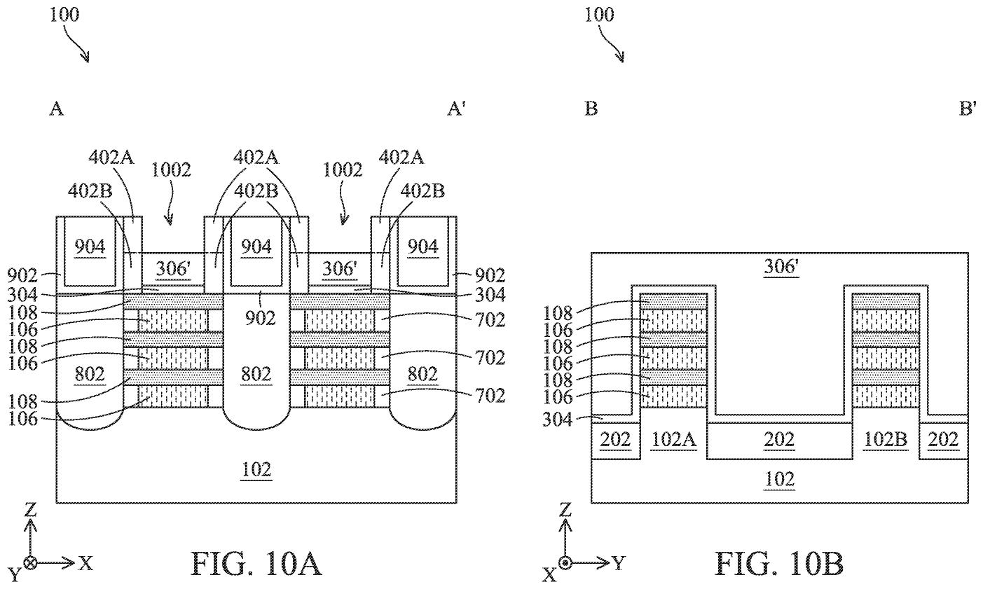

Referring to FIGS. 10A and 10B, a removal process is performed to partially remove the dummy gate structures 302 to form trenches 1002, in accordance with some embodiments. Specifically, a portion of each of the dummy gate electrode layers 306 is removed, so that the remaining portion of each of the dummy gate electrode layers 306 is remained to form a dummy gate electrode layer 306′, upper portions 402A of the gate spacers 402 are exposed, and the trenches 1002 are formed. In some embodiments, the trenches 1002 are formed over the dummy gate electrode layers 306′ and between the upper portions 402A of the gate spacers 402. In some embodiments, the upper portions 402A of the gate spacers 402 are exposed by the trenches 1002, and lower portions 402B of the gate spacers 402 are still covered by the dummy gate electrode layers 306′, as shown in FIG. 10A.

In some embodiments, the dummy gate structures 302 (i.e., the dummy gate electrode layers 306) are selectively and partially removed through any suitable lithography and etching processes to form trenches 1002. The lithography process may include forming a photoresist layer, exposing the photoresist to a pattern, performing a post-exposure bake process, and developing the photoresist to form a masking element, which exposes a region including the dummy gate structures 302. Then, the dummy gate structures 302 are selectively etched through the masking element. The gate spacers 402 may be used as the masking element or a part thereof. Etching selectivity may be achieved by selecting the appropriate etching chemicals, and the dummy gate electrode layers 306 may be partially removed without substantially affecting the CESL 902 and the ILD layer 904. In some embodiments, the etching process is configured to remove portions of the dummy gate electrode layers 306 only, and the dummy gate electrode layers 306′ are remained. The partial removal of the dummy gate electrode layers 306 creates the trenches 1002 that expose sidewalls of the upper portions 402A of the gate spacers 402 and top surfaces of the dummy gate electrode layers 306′. In other embodiments, the lithography process is omitted, and the partial removal of the dummy gate electrode layers 306 is performed based on the etching selectivity.

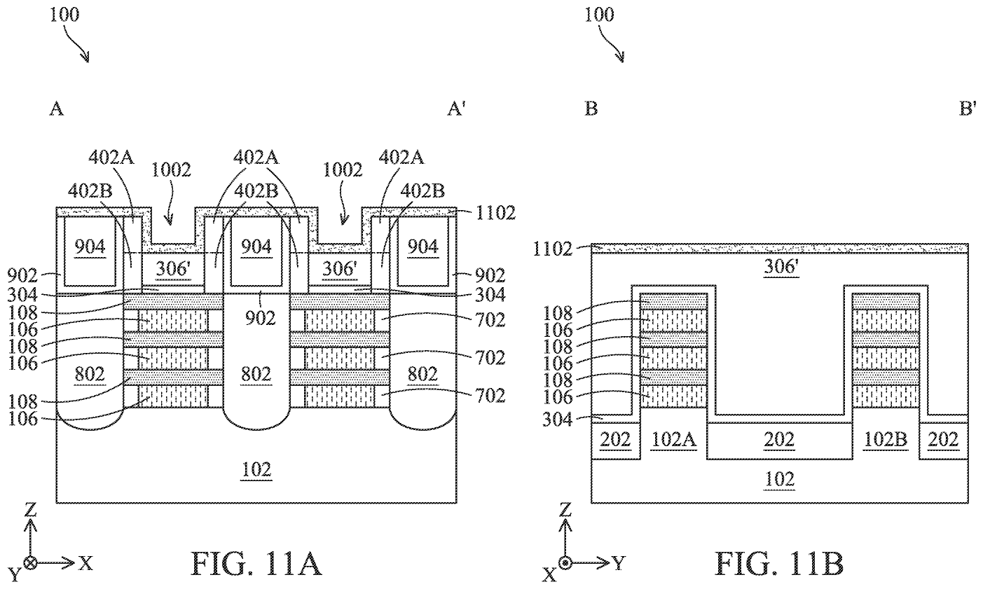

Referring to FIGS. 11A and 11B, insulating material layer 1102 is formed in the trenches 1002 and over the CESL 902 and the ILD layer 904, in accordance with some embodiments. Specifically, in some embodiments, the insulating material layer 1102 is conformally formed on the sidewalls of the upper portions 402A of the gate spacers 402 and over the top surfaces of the gate spacers 402, the dummy gate electrode layers 306′, the CESL 902, and the ILD layer 904. The insulating material layer 1102 may be a single layer structure or a multi-layer structure. In some embodiments, the insulating material layer 1102 may include La₂O₃, Al₂O₃, SiOCN, SiOC, SiCN, SiO₂, SiN, SiON, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. In some embodiments, the insulating material layer 1102 may include one or more low-k dielectric material including ELK dielectric material, such as those described herein. In some embodiments, the material of the insulating material layer 1102 is different from that of the gate spacers 402 to achieve desired etching selectivity during the following etching process. In some embodiments, the insulating material 1102 may be formed by CVD, PVD, ALD, HDPCVD, MOCVD, RPCVD, PECVD, LPCVD, ALCVD, APCVD, FCVD, other suitable methods, or combinations thereof.

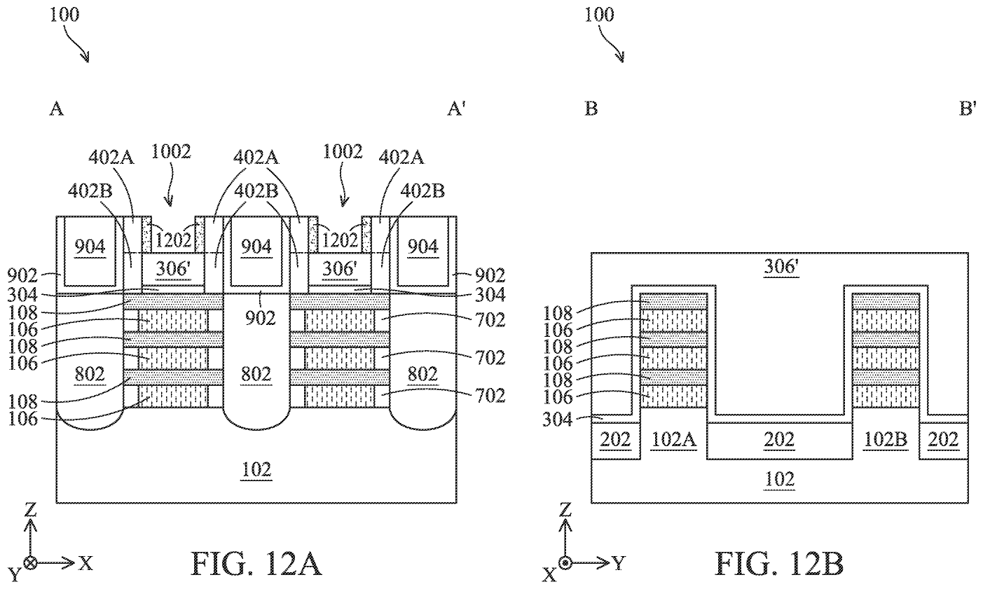

Referring to FIGS. 12A and 12B, a cap breakthrough process is performed to partially remove the insulating material layer 1102, so as to form insulating layers 1202 on sidewalls of the upper portion 402A of the gate spacers 402, in accordance with some embodiments. Specifically, horizontal portions of the insulating material layer 1102 over the top surfaces of the gate spacers 402, the dummy gate electrode layers 306′, the CESL 902, and the ILD layer 904 are removed, and vertical portions of the insulating material layer 1102 on the sidewalls of the upper portions 402A are remained to form insulating layers 1202 on the sidewalls of the upper portions 402A. In some embodiments, after the cap breakthrough process, the top surfaces of the dummy gate electrode layers 306′ are exposed in the trenches 1002. In some embodiments, the horizontal portions of the insulating material layer 1102 are removed through an anisotropic etching process, such as a dry etching process using plasma.

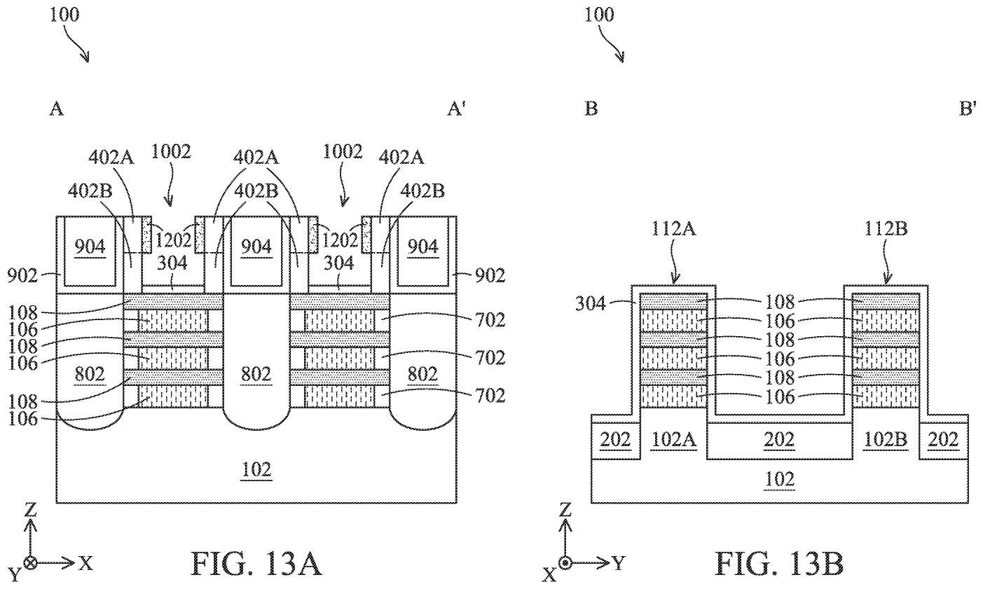

Referring to FIGS. 13A and 13B, the remaining portions of the dummy gate electrode layers 306 (i.e., the dummy gate electrode layers 306′) are remove to expose sidewalls of the lower portions 402B of the gate spacers 402, in accordance with some embodiments. Specifically, in some embodiments, the dummy gate electrode layers 306′ are removed through the trenches 1002 to expose the sidewalls of the lower portions 402B of the gate spacers 402 and the top surfaces of the dummy gate dielectric layers 304 in the trenches 1002. In these embodiments, the insulating layers 1202 are still remained on the sidewalls of the upper portions 402A of the gate spacers 402. In some embodiments, the removal of the dummy gate electrode layers 306′ is the same as or similar to the partial removal of the dummy gate electrode layers 306 as described with reference to FIGS. 10A and 10B, and is not repeated herein.

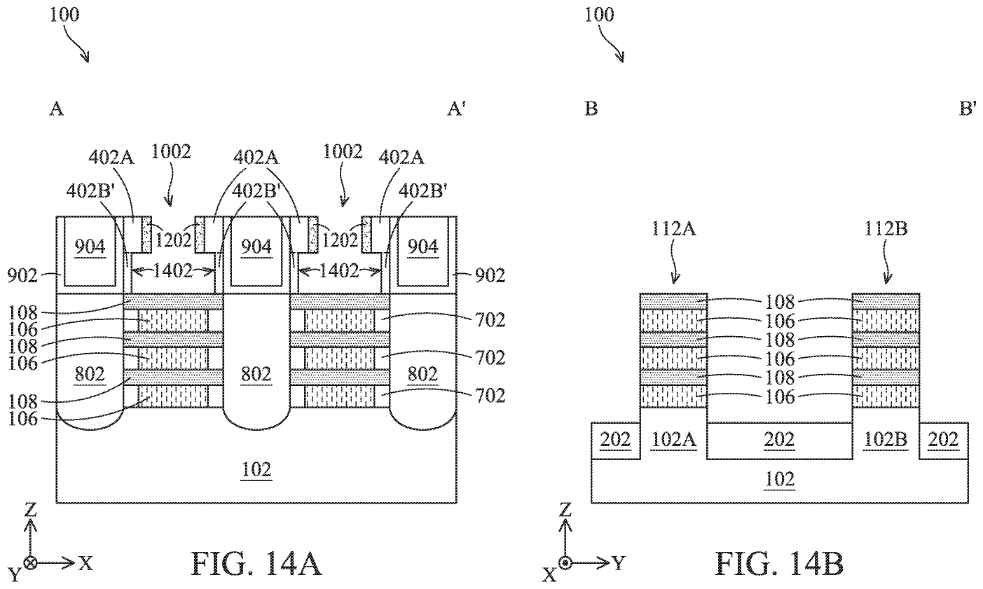

Referring to FIGS. 14A and 14B, the lower portions 402B of the gate spacers 402 are partially removed and the dummy gate dielectric layers 304 are removed, in accordance with some embodiments. In some embodiments, the partial removal of the lower portions 402B is also called sidewall trimming process. Specifically, in some embodiments, the dummy gate dielectric layers 304 are etched and the lower portions 402B of the gate spacers 402 are partially etched to form recesses 1402 in the trenches 1002, such that the width of the remaining portion of the lower portion 402B (i.e., the remaining lower portion 402B′ shown in FIG. 14A) is smaller than the width of the upper portion 402A in the X-direction, as shown in FIG. 14A. In these embodiments, due to the etching selectivity between the material of the insulating layers 1202 and the material of the gate spacers 402, the upper portions 402A of the gate spacers 402 are protected by the insulating layers 1202 formed on the sidewalls of the upper portions 402A during the etching process. Therefore, the lower portions 402B can be partially etched with minimal etching (or substantially no etching) the upper portions 402A, and thus the width of the remaining lower portion 402B′ is smaller than the width of the upper portion 402A, and the recesses 1402 are formed.

In some embodiments, the lower portions 402B of the gate spacers 402 are partially removed and the dummy gate dielectric layers 304 are removed by a selective etching process. The selective etching process is performed to selectively etch the dummy gate dielectric layers 304 and the side portions of the lower portions 402B through the trenches 1002, with minimal etching (or substantially no etching) the insulating layers 1202 (and the upper portions 402A protected by the insulating layers 1202) and the semiconductor layers 108. After the selective etching process, the recesses 1402 are formed between the upper portions 402A, the remaining lower portions 402B′, and the topmost semiconductor layers 108. In other words, for the trenches 1002, the spaces between the lower portions 402B are enlarged into the spaces between the remaining lower portions 402B′ through the selective etching process. In some embodiments, the selective etching process is configured to remove portions of the lower portions 402B only, and the remaining lower portions 402B′ are remained. The selective etching process may be a dry etching process, a wet etching process, other suitable etching process, or combinations thereof.

In some embodiments, the selective etching process is a single etching process, such as a wet etching process, with appropriate etching chemicals that may be used to etch the materials of the gate spacers 402 and the dummy gate dielectric layers 304 without substantially affecting the materials of the insulating layers 1202 and the semiconductor layers 108. In some embodiments, the selective etching process includes multiple etching processes. For example, a first etching process is performed to partially etch the lower portions 402B of the gate spacers 402 to form the remaining lower portions 402B′, and a second etching process is then performed to remove the dummy gate dielectric layers 304. In some alternative embodiments, a first etching process is performed to remove the dummy gate dielectric layers 304, and a second etching process is then performed to partially etch the lower portions 402B to form the remaining lower portions 402B′. In some embodiments, the selective etching process further includes forming a masking element that exposes a region including the trenches 1002 and covers other regions (e.g., the top surfaces of the upper portions 402A, the CESL 902, and the ILD layer 904).

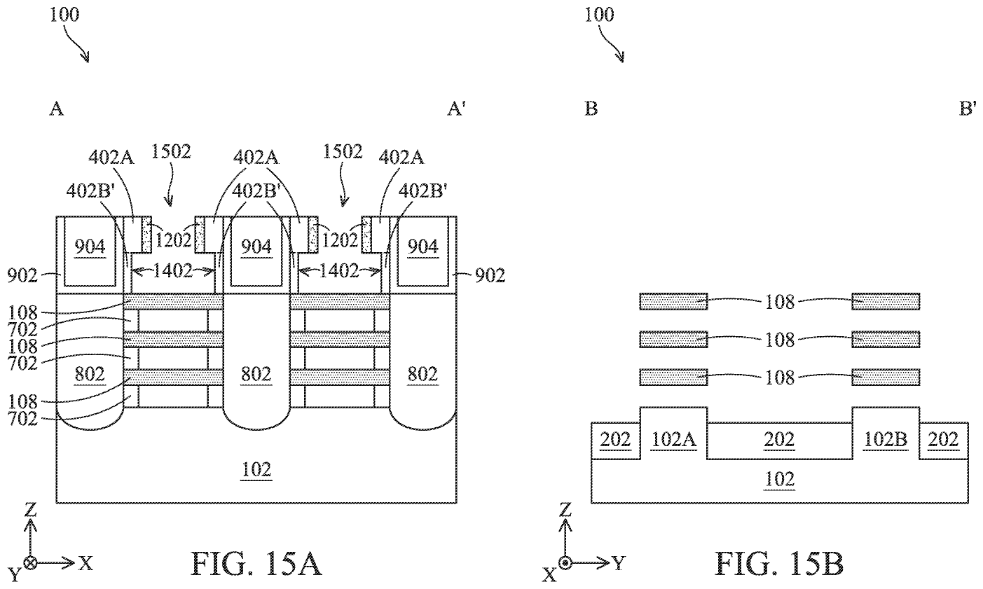

Referring to FIGS. 15A and 15B, the semiconductor layers 106 of the fin structures 112 are selectively removed through the trenches 1002 to form gate trenches 1502, using a wet or dry etching process for example, in accordance with some embodiments. After the semiconductor layers 106 are selectively removed, the semiconductor layers 108 are exposed in the gate trenches 1502 to form nanostructures stacked over each other. The nanostructures serve as channels, channel layers, or channel members for resultant transistors. As such, the semiconductor layers 108 may be referred to as nanostructures. Specifically, the semiconductor layers 108 are stacked over each other in the Z-direction. More specifically, the semiconductor layers 108 are suspended over and vertically arranged over the substrate 102 in the Z-direction, and constitute vertical stacks.

Such a process may also be referred to as a release process, a channel release process, a wire release process, a nanowire release process, a nanosheet release process, a nanowire formation process, a nanosheet formation process, a sheet formation process, or a wire formation process. In some embodiments, the removal of the semiconductor layers 106 causes the exposed semiconductor layers 108 to be spaced apart from each other in the vertical direction (e.g., in the Z-direction). The exposed semiconductor layers 108 extend longitudinally in the horizontal direction (e.g., in the X-direction). Furthermore, each of the semiconductor layers 108 connects one source/drain feature 802 to another source/drain feature 802.

In some embodiments, thicknesses of the semiconductor layers 108 exposed in the gate trenches 1502 may be reduced during the removal of the semiconductor layers 106. In some embodiments, the semiconductor layers 108 exposed in the gate trenches 1502 are also etched to have arc-shaped surfaces due to the etching process for removing the semiconductor layers 106. In other embodiments, heights of the base fins 102A and 102B in the gate trenches 1502 may also be reduced during the removal of the semiconductor layers 106. Furthermore, the thickness of the isolation structure 202 exposed in the gate trenches 1502 may also be reduced during the removal of the semiconductor layers 106. In certain embodiments, a sheet trimming process is performed to etch the semiconductor layers 108 to modify the profiles of the semiconductor layers 108.

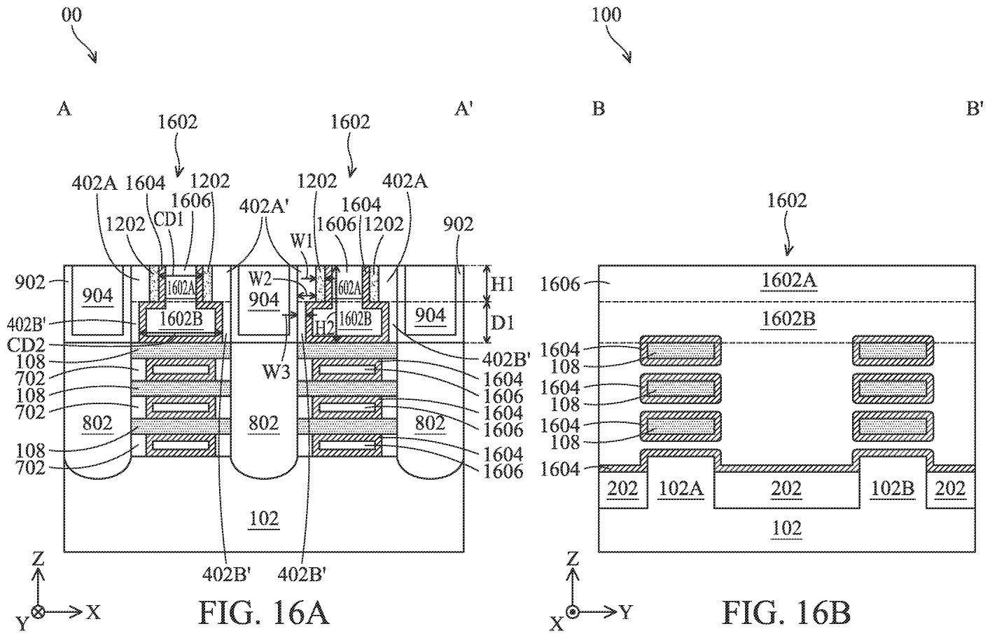

Referring to FIGS. 16A and 16B, gate structures 1602 are formed in the gate trenches 1502 to wrap around each of the exposed semiconductor layers 108, in accordance with some embodiments. As such, the gate structures 1502 replace the dummy gate structures 302. In some embodiments, the gate structures 1602 extend in the Y-direction. In some embodiments, the source/drain features 802 are formed on opposite sides of the gate structure 1602 in the X-direction, as shown in FIG. 16A.

In some embodiments, the gate structures 1602 each includes a gate dielectric layer 1604 and a gate electrode layer 1606 over the gate dielectric layer 1604. In some embodiments, the gate dielectric layers 1604 are formed to wrap around semiconductor layers 108 in the gate trenches 1502. In some embodiments, the gate dielectric layers 1604 are also formed on the sidewalls of the inner spacers 702, the remaining lower portions 402B′ of the gate spacers 402, and the insulating layers 1202, on the bottom surfaces of the insulating layers 1202 and the upper portions 402A of the gate spacers 402, and over the top surfaces of the isolation structure 202 and the base fins 102A, 102B.

The gate dielectric layers 1604 may include a dielectric material, such as SiOCN, SiOC, SiCN, SiO₂, SiN, SiC, or other suitable materials. In some embodiments, the gate dielectric layers 1604 may include a high-k dielectric material that has a dielectric constant greater than a dielectric constant of SiO₂, which is approximately 3.9. For example, the gate dielectric layers 1604 may include hafnium oxide (HfO₂), which has a dielectric constant in a range from about 18 to about 40. Alternatively, the gate dielectric layers 1604 may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃(STO), BaTiO₃(BTO), BaZrO, HfLaO, HfSiO, LaSiO, AlSiO, HfTaO, HfTiO, (Ba,Sr)TiO₃(BST), Al₂O₃, Si₃N₄, oxynitrides (SiON), combinations thereof, or other suitable materials. The gate dielectric layers 1604 may be formed by CVD, PVD, ALD, HDPCVD, MOCVD, RPCVD, PECVD, LPCVD, ALCVD, APCVD, FCVD, oxidation, and/or other suitable methods. In some embodiments, the material of the gate dielectric layer 1604 is different than the material of the insulating layer 1202.

In some embodiments, the gate structures 1602 each may further include an interfacial layer (not shown) formed to wrap around the exposed semiconductor layers 108 before the formation of the gate dielectric layers 1604, so that the gate dielectric layers 1604 are separated from the semiconductor layers 108 by the interfacial layers. In some embodiments, the interfacial layer may include a dielectric material such as silicon oxide (SiO₂), HfSiO, or silicon oxynitride (SiON). The interfacial layer may be formed by chemical oxidation, thermal oxidation, CVD, PVD, ALD, HDPCVD, MOCVD, RPCVD, PECVD, LPCVD, ALCVD, APCVD, FCVD, and/or other suitable method.

The gate electrode layers 1606 are formed to fill the remaining spaces of the gate trenches 1502, and over the gate dielectric layers 1604 in such a way that the gate electrode layers 1606 wrap around the semiconductor layers 108, the gate dielectric layer 1604, and the interfacial layers (if present). The gate electrode layers 1606 each may include a single layer or a multi-layer structure. In some embodiments, the gate electrode layers 1606 each may include a capping layer, a barrier layer, work function metal layers, and a fill material. The gate electrode layers 1606 may be formed using a deposition process such as CVD, PVD, ALD, HDPCVD, MOCVD, RPCVD, PECVD, LPCVD, ALCVD, APCVD, FCVD, or the like, although any suitable deposition process may be used. The capping layer may be formed of a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed of a material different from the capping layer. In some embodiments, the barrier layer may be formed of a material such as one or more layers of a metallic material. For example, the metallic material may be TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The work function layers may include conductive materials tuned to have a desired work function (e.g., an n-type work function or a p-type work function), such as n-type work function materials and/or p-type work function materials. In some embodiments, the p-type work function materials include TiN, TaN, Ru, Mo, Al, ZrSi₂, MoSi₂, TaSi₂, NiSi₂, WN, other p-type work function materials, or combinations thereof. In some embodiments, the n-type work function materials include Ti, Al, Ag, Mn, Zr, TiAl, TiAlC, TaC, TaCN, TaSiN, TaAl, TaAlC, TiAlN, other n-type work function materials, or combinations thereof. In some embodiments, the fill material may include a suitable conductive material, such as Al, W, and/or Cu.

Still referring to FIGS. 16A and 16B, the gate structure 1602 may be divided into an outer gate structure that is over the topmost one of the semiconductor layers 108 and an inner gate structure that is under the topmost one of the semiconductor layers 108, and the outer gate structure may include a first portion 1602A and a second portion 1602B, in accordance with some embodiments. In some embodiments, the first portion 1602A is between the upper portions 402A of the gate spacers 402, more specifically, between the insulating layers 1202 formed on the upper portions 402A. In some embodiments, the second portion 1602B is under the first portion 1602A and between the remaining lower portions 402B′ of the gate spacers 402.

In some embodiments, the insulating layer 1202 is between the upper portion 402A of the gate spacer 402 and the gate dielectric layer 1604 of the first portion 1602A of the gate structure 1602 in the X-direction, as shown in FIG. 16A. In these embodiments, the first portion 1602A of the gate structure 1602 is separated from the upper portions 402A by the insulating layer 1202. In some embodiments, the insulating layer 1202 is separated from the topmost one of the semiconductor layers 108 by the second portion 1602B of the gate structure 1602 in the Z-direction, as shown in FIG. 16A. In some embodiments, the gate dielectric layer 1604 of the second portion 1602B of the gate structure 1602 is in direct contact with the remaining lower portion 402B′ of the gate spacer 402.

In some embodiments, the insulating layer 1202 has a height H1 in a range from about 1 nm to about 22 nm in the Z-direction. In some embodiments, the height H1 is equal to the height of the first portion 1602A of the gate structure 1602 and the height of the upper portion 402A of the gate spacer 402. In some embodiments, the distance D1 between the insulating layer 1202 and the topmost one of the semiconductor layers 108 in the Z-direction is in a range from about 2 nm to about 23 nm. In some embodiments, the distance D1 is equal to the height of the second portion 1602B of the gate structure 1602 and the height of the remaining lower portion 402B′ of the gate spacer 402 in the Z-direction. In some embodiments, the outer gate structure of the gate structure 1602 has a height H2 that is equal to the sum of the height H1 and the distance D1 and is in a range from about 14 nm to about 24 nm. In some embodiments, the height of the inner gate structure of the gate structure 1602 (i.e., the distance from the top surface of the topmost one of the semiconductor layers 108 to the top surface of the substrate 102) is in a range from about 28 nm to about 53 nm.

In some embodiments, in the X-direction, the insulating layer 1202, the upper portion 402A of the gate spacer 402, and the remaining lower portion 402B′ of the gate spacer 402 have a width W1, a width W2, and a width W3, respectively. In some embodiments, the sum of the width W1 and the width W2 is greater than the width W3. In some embodiments, the width W2 is greater than the width W3. In some embodiments, in the X-direction, the first portion 1602A and the second portion 1602B of the gate structure 1602 have a critical dimension CD1 and a critical dimension CD2, respectively. In some embodiments, the critical dimension CD1 is smaller than the critical dimension CD2. That is, the width of the first portion 1602A is smaller than the width of the second portion 1602B in the X-direction. In some embodiments, the sum of the critical dimension CD1, twice the width W1, and twice the width W2 is substantially equal to the sum of the critical dimension CD2 and twice the width W3.

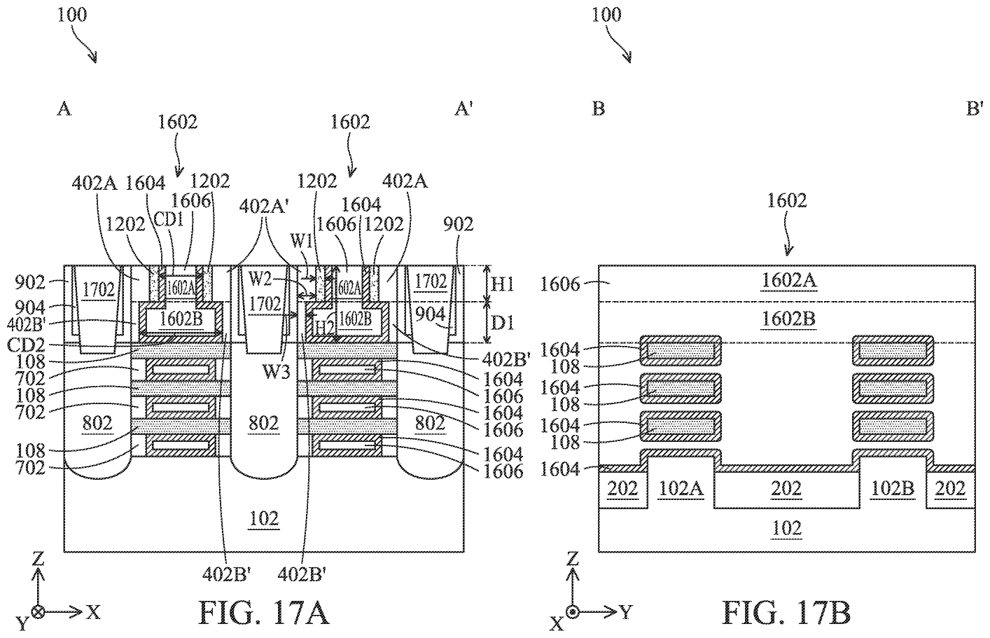

Referring to FIGS. 17A and 17B, source/drain contacts 1702 are formed over the source/drain features 802, and passing through the CESL 902 and the ILD layer 904, in accordance with some embodiments. In some embodiments, the source/drain contacts 1702 are on opposite sides of the gate structures 1602. In some embodiments, the source/drain contacts 1702 are separated from the first portions 1602A of the gate structures 1602 by the insulating layers 1202 and the upper portions 402A of the gate spacers 402. That is, the insulating layers 1202 and the upper portions 402A are sandwiched by the first portions 1602A and the source/drain contacts 1702. In some embodiments, a portion of each of the source/drain features 802 is removed during the formation of the source/drain contacts 1702. In these embodiments, the source/drain contacts 1702 extend into the source/drain features 802. In some embodiments, the source/drain contacts 1702 are in contact with and electrically connected to (a top surface of) the respective source/drain features 802. In some embodiments, the source/drain contact 1702 is funnel-shaped, which has a wider upper portion and a narrower lower portion.

The formation of the source/drain contacts 1702 may include forming contact openings passing through the CESL 902 and the ILD layer 904 and exposing the source/drain features 802, and depositing a conductive material in the contact openings. The conductive material of the source/drain contacts 1702 may include Al, Cu, W, Co, Ti, Ta, Ru, Rh, Ir, Pt, TiN, TiAl, TiAlN, TaN, TaC, combinations thereof, or the like, although any suitable material may be used. The source/drain contacts 1702 may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. However, any suitable materials and processes may be utilized to form source/drain contacts 1702. In some embodiments, the source/drain contacts 1702 may each include single conductive material layer or multiple conductive layers.

As shown in FIG. 17A, since the insulating layers 1202 are formed to protect the upper portions 402A of the gate spacers 402 from the sidewall trimming process (see FIGS. 14A-14B), the sidewalls of the upper portions of the outer gate structures (e.g., the first portions 1602A of the gate structures 1602) can keep straight instead of being enlarged to have funnel profiles. Moreover, the critical dimensions CD1 of the first portions 1602A can be maintained smaller since the first portions 1602A are separated from the contacts nearby (e.g., the source/drain contacts 1702) by the insulating layers 1202 and the upper portions 402A that are not affected during the sidewall trimming process. Therefore, the distances between the first portions 1602A of the gate structures 1602 and the source/drain contacts 1702 will not be decreased during the sidewall trimming process. That is, compared with the conventional gate structure with funnel profile, the distances between the first portions 1602A of the gate structures 1602 and the source/drain contacts 1702 are increased. Therefore, the process window of forming the source/drain contacts 1702 can be increased since the risk that the material of the source/drain contacts 1702 contacts the gate structures 1602 during the formation is reduced, and the leakage between the gate structures 1602 and the source/drain contacts 1702 can be decreased. Furthermore, since the first portions 1602A of the gate structures 1602 are smaller and the distances between the first portions 1602A and the source/drain contacts 1702 are greater, the capacitances between the gate structures 1602 and the source/drain contacts 1702 can also be reduced. In addition, dimensions of the lower portion of the outer gate structures (e.g., the critical dimension CD2 of the second portions 1602B of the gate structures 1602) can be modulated flexibly to satisfy various design requirements.

In some embodiments, the workpiece 100 may further undergo a formation process of a gate isolation structure to separate the gate structure. For example, a cut metal gate (CMG) process may be performed to separate the gate structure into two or more segments. Alternatively, a cut poly (CPO) process may be performed to separate the gate structure into two or more segments.

Referring to FIG. 18A, a CMG process is performed to form a gate isolation structure 1802 in the gate structure 1602 to divided the gate structure 1602 into two segments in the Y-direction, in accordance with some embodiments. In some embodiments, the gate isolation structure 1802 extends in the X-direction. In some embodiments, the CMG process is performed after the formation of the gate structure 1602. For example, the CMG process is performed after the fabrication stage described with reference to FIGS. 16A and 16B. The formation of the gate isolation structure 1802 may include forming a gate isolation trench through the gate structure 1602 and exposing the top surface of the isolation structure 202, and depositing a dielectric material in the gate isolation trench. In some embodiments, the gate isolation trench extends into the isolation structure 202, and thus the gate isolation structure 1802 formed therein also extends into the isolation structure 202. In some embodiments, since the gate isolation structure 1802 is formed after the gate structure 1602, the gate isolation structure 1802 pass through the gate dielectric layer 1604 formed on the isolation structure 202, as shown in FIG. 18A.

The dielectric material of the gate isolation structure 1802 may include SiN, SiO₂, SiC, SiON, SiOC, SiCN, SiOCN, ZrSiO₂, HfO₂, HfSiO₄, LaO, Al₂O₃, combinations thereof, or the like, although any suitable material may be used. The gate isolation structure 1802 may include a single layer or a multi-layer structure. In some embodiments, the gate isolation structure 1802 may include a first dielectric layer made of silicon nitride, and a second dielectric layer made of silicon oxide and formed on the first dielectric layer. In some embodiments, the material of the gate isolation structure 1802 is different than the material of the gate spacers 402. The gate isolation structure 1802 may be formed using a deposition process such as CVD, PVD, ALD, HDPCVD, MOCVD, RPCVD, PECVD, LPCVD, ALCVD, APCVD, FCVD, other suitable methods, or combinations thereof.

Referring to FIG. 18B, a CPO process is performed to form a gate isolation structure 1804 in the gate structure 1602 to divided the gate structure 1602 into two segments in the Y-direction, in accordance with some embodiments. In some embodiments, the gate isolation structure 1804 extends in the X-direction. In some embodiments, the CPO process is performed after the formation of the dummy gate structure 302 and before the formation of the gate structure 1602. For example, the CPO process is performed after the fabrication stage described with reference to FIGS. 4A and 4B and before the fabrication stage described with reference to FIGS. 9A and 9B. The formation of the gate isolation structure 1804 may include forming a gate isolation trench through the dummy gate structure 302 and exposing the top surface of the isolation structure 202, and depositing a dielectric material in the gate isolation trench. In some embodiments, the gate isolation trench extends into the isolation structure 202, and thus the gate isolation structure 1804 formed therein also extends into the isolation structure 202.

In some embodiments, since the gate isolation structure 1804 is formed before the gate structure 1602, the insulating layers 1202 and the gate dielectric layers 1604 are also formed on sidewalls of the gate isolation structure 1804, as shown in FIG. 18B. In some embodiments, the insulating layers 1202 are formed on sidewalls of the upper portion of the gate isolation structure 1804, and the gate dielectric layers 1604 are formed on the insulating layers 1202 and on sidewalls of the other portion of the gate isolation structure 1804. That is, the upper portion of the gate isolation structure 1804 is separated from the gate dielectric layers 1604 by the insulating layers 1202 in the Y-direction, and the insulating layers 1202 formed on sidewalls of the upper portion of the gate isolation structure 1804 are separated from the isolation structure 202 and/or the substrate 102 by the gate dielectric layers 1604 in the Z-direction, as shown in FIG. 18B. In some embodiments, the distance D2 between the bottom surface of the insulating layer 1202 and the top surface of the isolation structure 202 or the substrate 102 (in the embodiments where the isolation structure 202 is omitted) is in a range from about 30 nm to about 76 nm in the Z-direction. The configuration, material, and the forming method of the gate isolation structure 1804 are the same as or similar to that of the gate isolation structure 1802, and are not repeated herein.

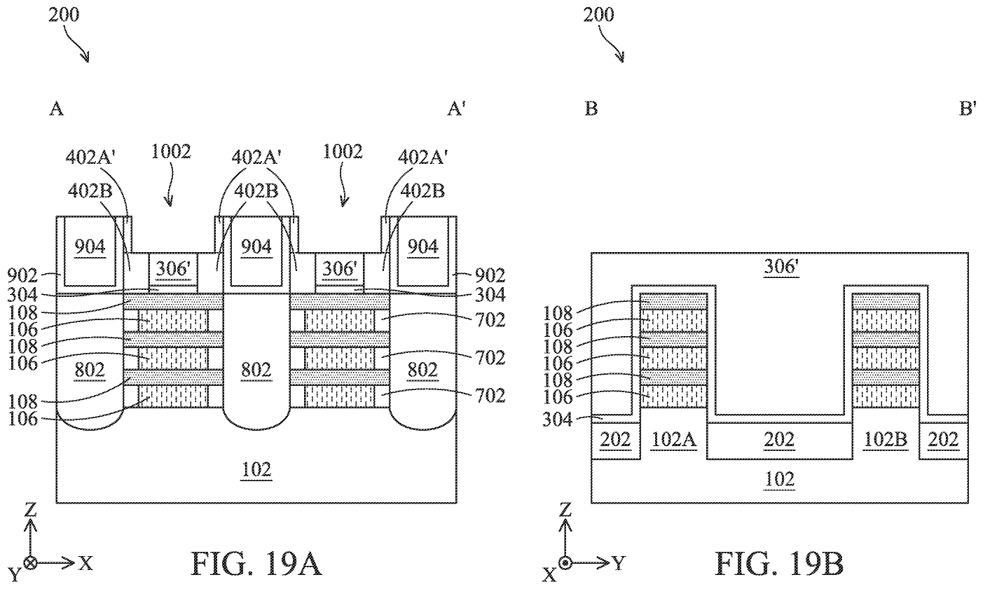

FIGS. 19A to 26A are X-Z cross-sectional views of the workpiece 200 at various fabrication stages along a line A-A′ of FIG. 2, in accordance with some alternative embodiments of the present disclosure. FIGS. 19B to 26B are Y-Z cross-sectional views of the workpiece 200 at various fabrication stages along a line B-B′ of FIG. 2, in accordance with some alternative embodiments of the present disclosure. Since the workpiece 200 will be fabricated into a semiconductor structure 200 upon conclusion of the fabrication processes, the workpiece 200 may be referred to as the semiconductor structure 200 as the context requires. The fabrication stage shown in FIGS. 19A and 19B follows the fabrication stage shown in FIGS. 10A and 10B.

Referring to FIGS. 19A and 19B, the upper portions 402A of the gate spacers 402 are partially removed to form remaining upper portions 402A′, in accordance with some embodiments. In some embodiments, the partial removal of the upper portions 402A is also called the first sidewall trimming process. Specifically, in some embodiments, the upper portions 402A are partially etched and thus the trenches 1002 are enlarged in the X-direction, such that the width of the remaining portion of the upper portion 402A (i.e., the remaining upper portion 402A′ shown in FIG. 19A) is smaller than the width of the lower portion 402B in the X-direction, as shown in FIG. 19A. In some embodiments, the top surfaces of portions of the lower portions 402B are exposed in the trenches 1002 due to the partial removal of the upper portions 402A.

In some embodiments, the upper portions 402A of the gate spacers 402 are partially removed by a selective etching process. The selective etching process is performed to selectively etch the side portions of the upper portions 402A through the trenches 1002, with minimal etching (or substantially no etching) of the dummy gate electrode layers 306′, the CESL 902, and the ILD layer 904. After the selective etching process, in the X-direction, the widths between the upper portions 402A are increased into the widths between the remaining upper portions 402A′. In other words, for the trenches 1002, the spaces between the upper portions 402A are enlarged into the spaces between the remaining upper portions 402A′ through the selective etching process. In some embodiments, the selective etching process is configured to remove portions of the upper portions 402A only, and the remaining upper portions 402A′ are remained. The selective etching process may be a dry etching process, a wet etching process, other suitable etching process, or combinations thereof. In some embodiments, the selective etching process further includes forming a masking element that exposes a region including the trenches 1002 and covers other regions (e.g., portions of the top surfaces of the upper portions 402A, and the top surfaces of CESL 902 and the ILD layer 904).

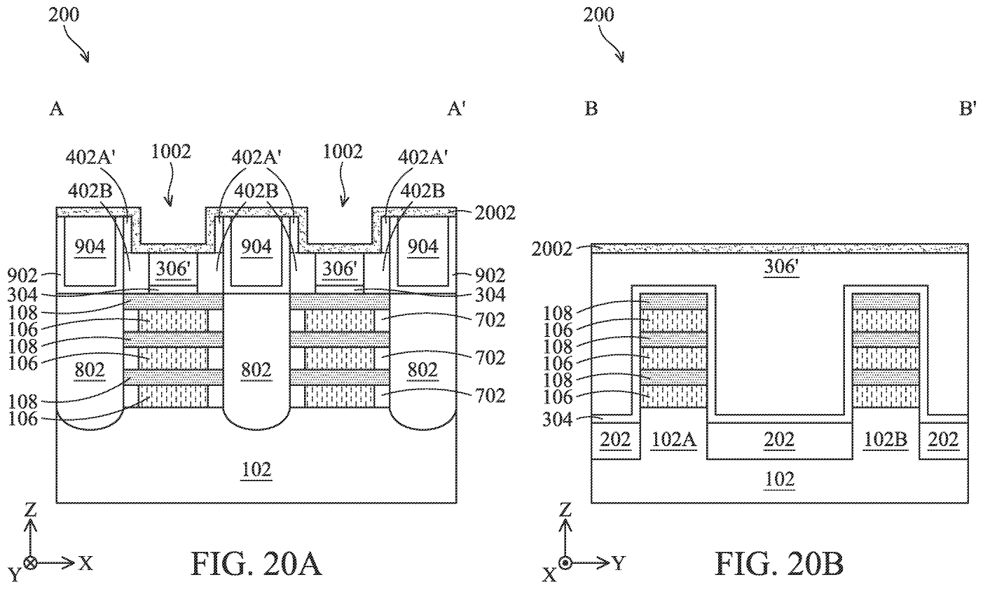

Referring to FIGS. 20A and 20B, insulating material layer 2002 is formed in the trenches 1002 and over the CESL 902 and the ILD layer 904, in accordance with some embodiments. Specifically, in some embodiments, the insulating material layer 2002 is conformally formed on the sidewalls of the remaining upper portions 402A′ of the gate spacers 402 and over top surfaces of the remaining upper portions 402A′, the lower portions 402B, the dummy gate electrode layers 306′, the CESL 902, and the ILD layer 904. The configuration, material, and forming method of the insulating material layer 2002 may be the same as or similar to that of the insulating material layer 1102, and are not repeated herein.

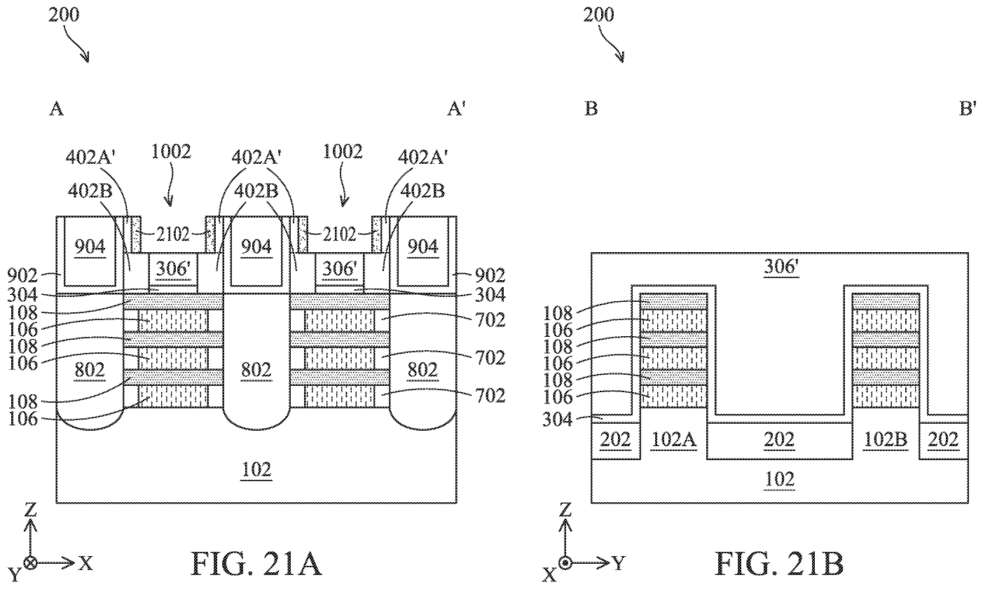

Referring to FIGS. 21A and 21B, a cap breakthrough process is performed to partially remove the insulating material layer 2002, so as to form insulating layers 2102 on sidewalls of the remaining upper portion 402A′ of the gate spacers 402, in accordance with some embodiments. Specifically, horizontal portions of the insulating material layer 2002 over the top surfaces of the remaining upper portions 402A′, the lower portions 402B, the dummy gate electrode layers 306′, the CESL 902, and the ILD layer 904 are removed, and vertical portions of the insulating material layer 2002 on the sidewalls of the remaining upper portions 402A′ are remained to form insulating layers 2102 on the sidewalls of the remaining upper portions 402A′. In some embodiments, after the cap breakthrough process, the top surfaces of the dummy gate electrode layers 306′ are exposed in the trenches 1002. In some embodiments, the horizontal portions of the insulating material layer 2002 are removed through an anisotropic etching process, such as a dry etching process using plasma.

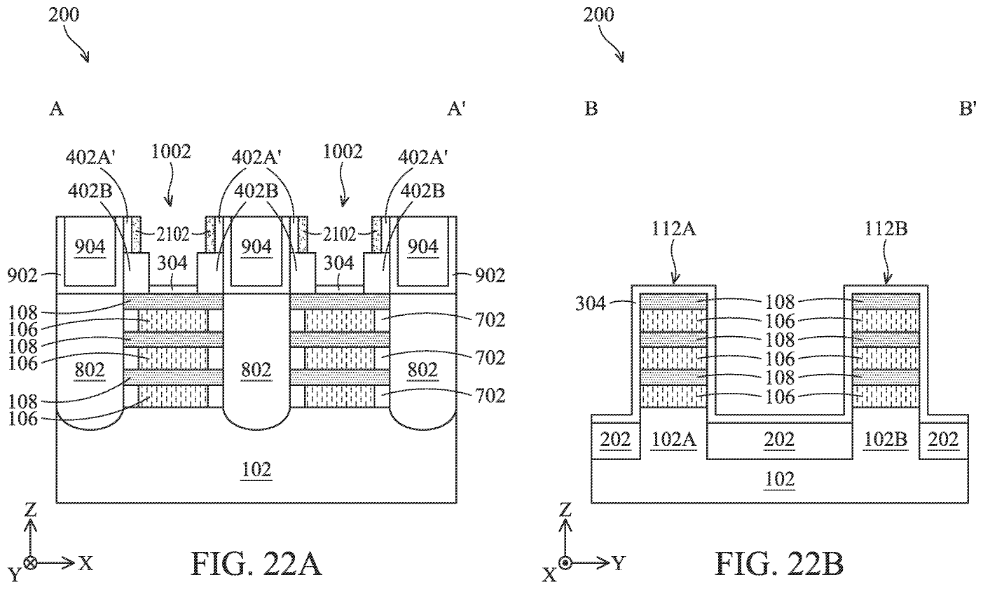

Referring to FIGS. 22A and 22B, the remaining portions of the dummy gate electrode layers 306 (i.e., the dummy gate electrode layers 306′) are remove to expose sidewalls of the lower portions 402B of the gate spacers 402, in accordance with some embodiments. Specifically, in some embodiments, the dummy gate electrode layers 306′ are removed through the trenches 1002 to expose the sidewalls of the lower portions 402B and the top surfaces of the dummy gate dielectric layers 304 in the trenches 1002. In these embodiments, the insulating layers 2102 are still remained on the sidewalls of the remaining upper portions 402A′ of the gate spacers 402. In some embodiments, the removal of the dummy gate electrode layers 306′ is the same as or similar to the partial removal of the dummy gate electrode layers 306 as described with reference to FIGS. 10A and 10B, and is not repeated herein.

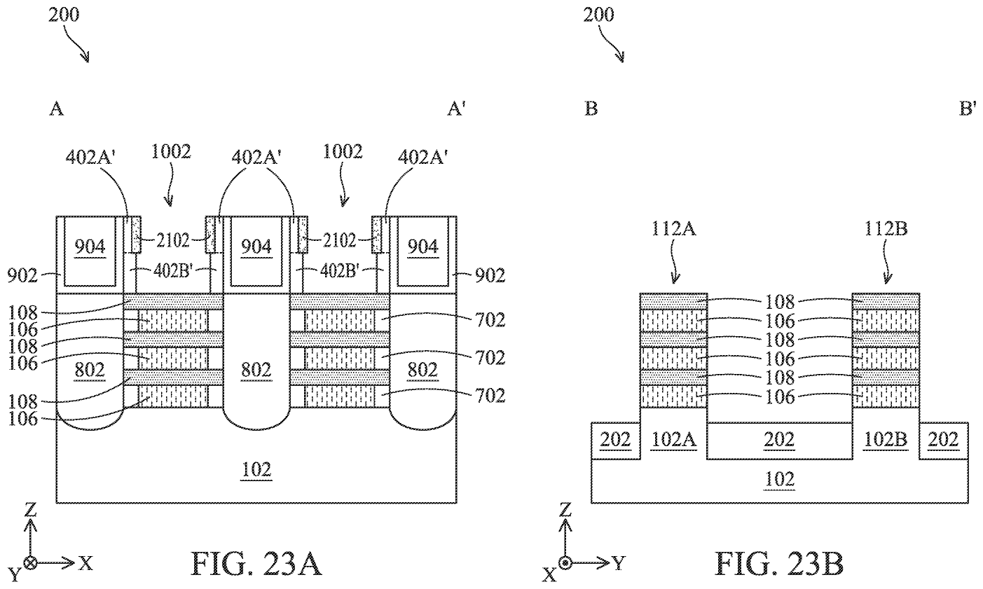

Referring to FIGS. 23A and 23B, the lower portions 402B of the gate spacers 402 are partially removed and the dummy gate dielectric layers 304 are removed, in accordance with some embodiments. In some embodiments, the partial removal of the lower portions 402B is also called the second sidewall trimming process. Specifically, in some embodiments, the dummy gate dielectric layers 304 are etched and the lower portions 402B of the gate spacers 402 are partially etched. As a result, the width of the lower portions 402B is decreased into the width of remaining portion of the lower portion 402B (i.e., the remaining lower portion 402B′ shown in FIG. 23A) in the X-direction, and thus the space of the trench 1002 between the lower portions 402B is enlarged, as shown in FIG. 23A. In these embodiments, due to the etching selectivity between the material of insulating layers 2102 and the material of the gate spacers 402, the remaining upper portions 402A′ of the gate spacers 402 are protected by the insulating layers 2102 formed on the sidewalls of the remaining upper portions 402A′ during the etching process. Therefore, the lower portions 402B can be partially etched with minimal etching (or substantially no etching) the remaining upper portions 402A′. Since the upper portion 402A is partially etched through the first sidewall trimming process and the lower portions 402B is partially etched through the second sidewall trimming process different than the first sidewall trimming process, the width of the remaining upper portion 402A′ and the width of the remaining lower portion 402B′ may be modulated independently without affecting each other.

In some embodiments, the lower portions 402B of the gate spacers 402 are partially removed and the dummy gate dielectric layers 304 are removed by a selective etching process. The selective etching process is performed to selectively etch the dummy gate dielectric layers 304 and the side portions of the lower portions 402B through the trenches 1002, with minimal etching (or substantially no etching) of the insulating layers 2102 (and the remaining upper portions 402A′ protected by the insulating layers 2102) and the semiconductor layers 108. After the selective etching process, for the trenches 1002, the spaces between the lower portions 402B are enlarged into the spaces between the remaining lower portions 402B′ through the selective etching process. In some embodiments, the selective etching process is configured to remove portions of the lower portions 402B only, and the remaining lower portions 402B′ are remained. The selective etching process may be a dry etching process, a wet etching process, other suitable etching process, or combinations thereof.

In some embodiments, the selective etching process is a single etching process, such as a wet etching process, with appropriate etching chemicals that may be used to etch the materials of the gate spacers 402 and the dummy gate dielectric layers 304 without substantially affecting the materials of the insulating layers 2102 and the semiconductor layers 108. In some embodiments, the selective etching process includes multiple etching processes. For example, a first etching process is performed to partially etch the lower portions 402B of the gate spacers 402 to form the remaining lower portions 402B′, and a second etching process is then performed to remove the dummy gate dielectric layers 304. In some alternative embodiments, a first etching process is performed to remove the dummy gate dielectric layers 304, and a second etching process is then performed to partially etch the lower portions 402B to form the remaining lower portions 402B′. In some embodiments, the selective etching process further includes forming a masking element that exposes a region including the trenches 1002 and covers other regions (e.g., the top surfaces of the remaining upper portions 402A′, the CESL 902, and the ILD layer 904).

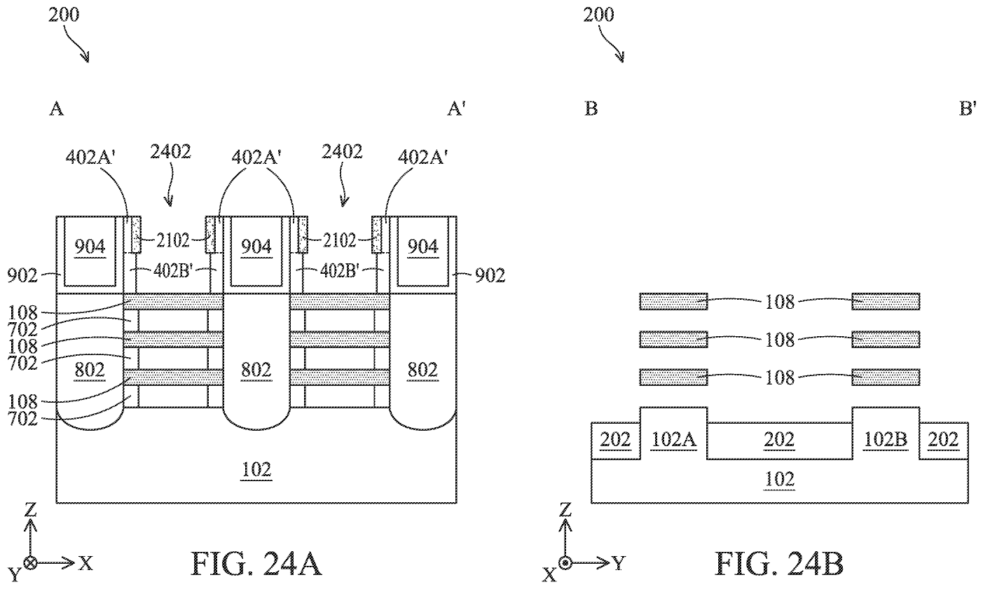

Referring to FIGS. 24A and 24B, the semiconductor layers 106 of the fin structures 112 are selectively removed through the trenches 1002 to form gate trenches 2402, using a wet or dry etching process for example, in accordance with some embodiments. After the semiconductor layers 106 are selectively removed, the semiconductor layers 108 are exposed in the gate trenches 2402 to form nanostructures stacked over each other. The nanostructures serve as channels, channel layers, or channel members for resultant transistors. As such, the semiconductor layers 108 may be referred to as nanostructures. Specifically, the semiconductor layers 108 are stacked over each other in the Z-direction. More specifically, the semiconductor layers 108 are suspended over and vertically arranged over the substrate 102 in the Z-direction, and constitute vertical stacks. In some embodiments, the removal of the semiconductor layers 106 shown in FIGS. 24A and 24B is the same as or similar to the removal of the semiconductor layers 106 as described with reference to FIGS. 15A and 15B, and is not repeated herein.

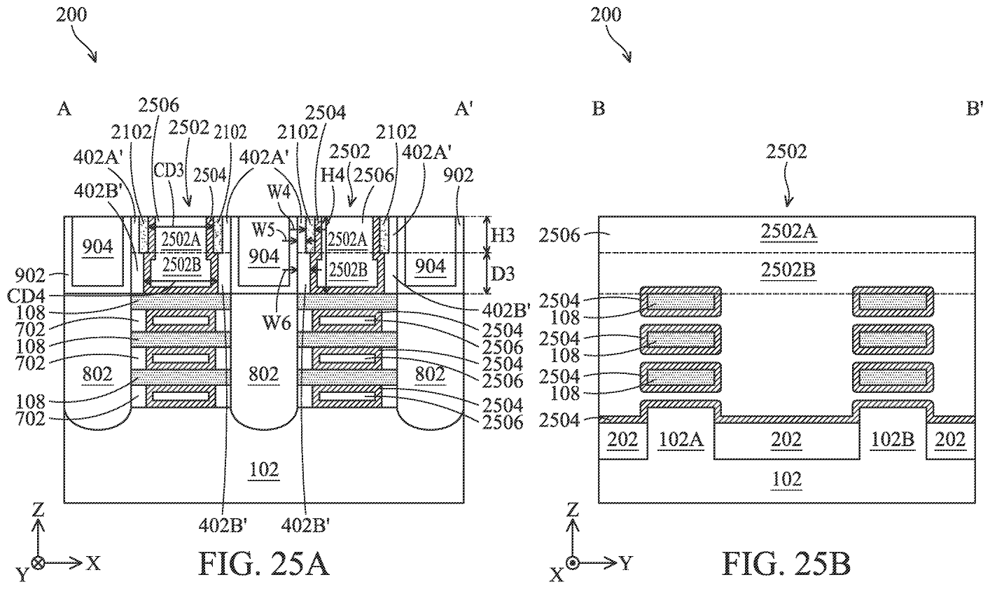

Referring to FIGS. 25A and 25B, gate structures 2502 are formed in the gate trenches 2402 to wrap around the exposed semiconductor layers 108, in accordance with some embodiments. As such, the gate structures 2502 replace the dummy gate structures 302. In some embodiments, the gate structures 2502 extend in the Y-direction. In some embodiments, the source/drain features 802 are formed on opposite sides of the gate structure 2502 in the X-direction, as shown in FIG. 25A.

In some embodiments, the gate structures 2502 each includes a gate dielectric layer 2504 and a gate electrode layer 2506 over the gate dielectric layer 2504. In some embodiments, the gate dielectric layers 2504 are formed to wrap around semiconductor layers 108 in the gate trenches 2402. In some embodiments, the gate dielectric layers 2504 are also formed on the sidewalls of the inner spacers 702, the remaining lower portions 402B′ of the gate spacers 402, and the insulating layers 2102, on the bottom surfaces of the insulating layers 2102, and over the top surfaces of the isolation structure 202 and the base fins 102A, 102B.

The configuration, material, and forming method of the gate structures 2502 (including the gate dielectric layers 2504 and the gate electrode layers 2506) are the same as or similar to that of the gate structures 1602 described previously, and are not repeated herein. In some embodiments, the material of the gate dielectric layer 2504 is different than the material of the insulating layer 2102. In some embodiments, the gate electrode layers 2506 fill the remaining spaces of the gate trenches 2402, and over the gate dielectric layers 2504 in such a way that the gate electrode layers 2506 wrap around the semiconductor layers 108, the gate dielectric layer 2504, and the interfacial layers (if present).

Still referring to FIGS. 25A and 25B, the gate structure 2502 may be divided into an outer gate structure that is over the topmost one of the semiconductor layers 108 and an inner gate structure that is under the topmost one of the semiconductor layers 108, and the outer gate structure may include a first portion 2502A and a second portion 2502B, in accordance with some embodiments. In some embodiments, the first portion 2502A is between the remaining upper portions 402A′ of the gate spacers 402, more specifically, between the insulating layers 2102 formed on the sidewalls of the remaining upper portions 402A′. In some embodiments, the second portion 2502B is under the first portion 2502A and between the remaining lower portions 402B′ of the gate spacers 402.

In some embodiments, the insulating layer 2102 is between the remaining upper portion 402A′ of the gate spacer 402 and the gate dielectric layer 2504 of the first portion 2502A of the gate structure 2502 in the X-direction, as shown in FIG. 25A. In these embodiments, the first portion 2502A of the gate structure 2502 is separated from the remaining upper portions 402A′ by the insulating layer 2102. In some embodiments, the insulating layer 2102 is separated from the topmost one of the semiconductor layers 108 by the second portion 2502B of the gate structure 2502 and/or the remaining lower portions 402B′ in the Z-direction, as shown in FIG. 25A. In some embodiments, the gate dielectric layer 2504 of the second portion 2502B of the gate structure 2502 is in direct contact with the remaining lower portion 402B′ of the gate spacer 402.

In some embodiments, the insulating layer 2102 has a height H3 in a range from about 1 nm to about 22 nm in the Z-direction. In some embodiments, the height H3 is equal to the height of the first portion 2502A of the gate structure 2502 and the height of the remaining upper portion 402A′ of the gate spacer 402. In some embodiments, the distance D3 between the insulating layer 2102 and the topmost one of the semiconductor layers 108 in the Z-direction is in a range from about 2 nm to about 23 nm. In some embodiments, the distance D3 is equal to the height of the second portion 2502B of the gate structure 2502 and the height of the remaining lower portion 402B′ of the gate spacer 402 in the Z-direction. In some embodiments, the outer gate structure of the gate structure 2502 has a height H4 that is equal to the sum of the height H3 and the distance D3 and is in a range from about 14 nm to about 24 nm. In some embodiments, the height of the inner gate structure of the gate structure 2502 (i.e., the distance from the top surface of the topmost one of the semiconductor layers 108 to the top surface of the substrate 102) is in a range from about 28 nm to about 53 nm.

In some embodiments, in the X-direction, the insulating layer 2102, the remaining upper portion 402A′ of the gate spacer 402, and the remaining lower portion 402B′ of the gate spacer 402 have a width W4, a width W5, and a width W6, respectively. In some embodiments, the sum of the width W4 and the width W5 is greater than the width W6. In other embodiments, the sum of the width W4 and the width W5 is smaller than the width W6. In some embodiments, the width W5 is smaller than the width W6. In other embodiments, the width W5 is greater than the width W6. In some embodiments, in the X-direction, the first portion 2502A and the second portion 2502B of the gate structure 2502 have a critical dimension CD3 and a critical dimension CD4, respectively. In some embodiments, the critical dimension CD3 is smaller than the critical dimension CD4 (i.e., the sum of the width W4 and the width W5 is greater than the width W6). That is, the width of the first portion 2502A is smaller than the width of the second portion 2502B in the X-direction. In other embodiments, the critical dimension CD3 is greater than the critical dimension CD4 (i.e., the sum of the width W4 and the width W5 is smaller than the width W6). That is, the width of the first portion 2502A is greater than the width of the second portion 2502B in the X-direction. As described above, the width W5 of the remaining upper portion 402A′ and the width W6 of the remaining lower portion 402B′ may be modulated independently through the first and second sidewall trimming processes. Therefore, the critical dimension CD3 and the critical dimension CD4 of the gate structure 2502 may also be modulated independently to satisfy various design requirements. In some embodiments, the sum of the critical dimension CD3, twice the width W4, and twice the width W5 is substantially equal to the sum of the critical dimension CD4 and twice the width W6.

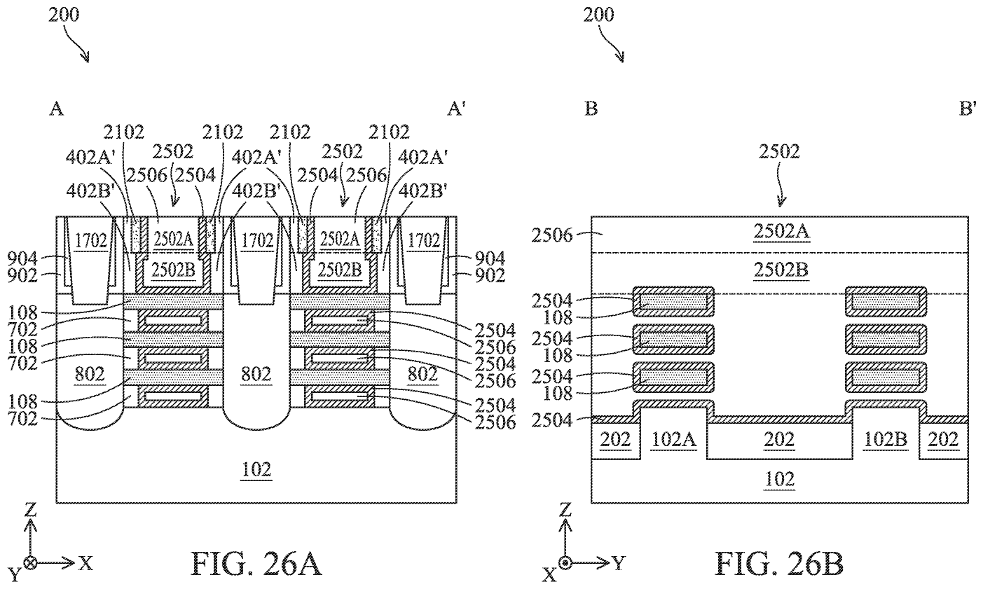

Referring to FIGS. 26A and 26B, source/drain contacts 1702 are formed over the source/drain features 802, and passing through the CESL 902 and the ILD layer 904, in accordance with some embodiments. In some embodiments, the source/drain contacts 1702 are on opposite sides of the gate structures 1602. In some embodiments, the source/drain contacts 1702 are separated from the first portions 2502A of the gate structures 2502 by the insulating layers 2102 and the remaining upper portions 402A′ of the gate spacers 402. That is, the insulating layers 2102 and the remaining upper portions 402A′ are sandwiched by the first portions 2502A and the source/drain contacts 1702. The configuration, material, forming method of the source/drain contact 1702 have been described with reference to FIGS. 17A and 17B, and are not repeated herein.

As shown in FIG. 26A, since the insulating layers 2102 are formed to protect the remaining upper portions 402A′ of the gate spacers 402 from the second sidewall trimming process for the lower portions 402B of the gate spacers 402 (see FIGS. 23A-23B), the sidewalls of the upper portions of the outer gate structures (e.g., the first portions 2502A of the gate structures 2502) can keep straight instead of being enlarged to have funnel profiles. Moreover, the critical dimensions CD3 of the first portions 2502A can be maintained smaller since the first portions 2502A are separated from the contacts nearby (e.g., the source/drain contacts 1702) by the insulating layers 2102 and the remaining upper portions 402A′ that are not affected during the second sidewall trimming process. Therefore, the distances between the first portions 2502A of the gate structures 2502 and the source/drain contacts 1702 will not be decreased during the second sidewall trimming process. That is, compared with the conventional gate structure with funnel profile, the distances between the first portions 2502A of the gate structures 2502 and the source/drain contacts 1702 are increased. Therefore, the process window of forming the source/drain contacts 1702 can be increased since the risk that the material of the source/drain contacts 1702 contacts the gate structures 2502 during the formation is reduced, and the leakage between the gate structures 2502 and the source/drain contacts 1702 can be decreased.

Furthermore, since the first portions 2502A of the gate structures 2502 are smaller and the distances between the first portions 2502A and the source/drain contacts 1702 are greater, the capacitances between the gate structures 2502 and the source/drain contacts 1702 can also be reduced. In addition, since the sidewall trimming process is divided into first and second sidewall trimming processes for upper portions 402A and lower portions 402B of the gate spacers 402, respectively, dimensions of the upper portion and the lower portion of the outer gate structures (e.g., the critical dimension CD3 of the first portions 2502A the critical dimension CD4 of the second portions 2502B of the gate structures 2502) can be modulated independently and flexibly to satisfy various design requirements.

In some embodiments, the workpiece 200 may further undergo a formation process of a gate isolation structure to separate the gate structure. For example, the workpiece 200 may include the gate isolation structure 1802 described with reference to FIG. 18A, or the gate isolation structure 1804 described with reference to FIG. 18B.

Embodiments of the present disclosure offer advantages over the existing art, though it is understood that other embodiments may offer different advantages, not all advantages are necessarily discussed herein, and no particular advantage is required for all embodiments. The embodiments disclosed herein relate to semiconductor structures and their forming methods, and more particularly to methods and semiconductor structures including insulating layers formed on sidewalls of the upper portions of the gate spacers. The insulating layers are between the upper portions of the gate spacers and the upper portion of the gate structure. The insulating layers can protect the upper portions of the gate spacers from the removal processes, such as the sidewall trimming process, and thus the sidewalls of the gate structure can keep straight and the critical dimension of the upper portion of the gate structure can be maintained smaller instead of being enlarged to have funnel profile. Therefore, the process window of the contacts nearby can be increased and the leakage between the gate structure and the contacts nearby can be decreased. Moreover, the embodiments disclosed herein further include dividing sidewall trimming process into at least two sidewall trimming processes used for different portions of the gate spacers. Through combining forming the insulating layers and dividing sidewall trimming process, the critical dimensions of the upper portion and the lower portion of the outer gate structure can be modulated independently and flexibly to satisfy various design requirements.

Thus, one of the embodiments of the present disclosure describes a method of forming a semiconductor structure. The method includes forming a fin structure over a substrate in a Z-direction; forming a dummy gate structure extending in a Y-direction and over the fin structure; and forming gate spacers on sidewalls of the dummy gate structure. The fin structure includes first semiconductor layers and second semiconductor layers alternately stacked. The method further includes removing a portion of the dummy gate structure to form a first trench that exposes upper portions of the gate spacers; forming an insulating material in the first trench; partially removing the insulating material to form insulating layers on sidewalls of the upper portions of the gate spacers; removing a remaining portion of the dummy gate structure to expose lower portions of the gate spacers; and partially etching the lower portions of the gate spacers.

In some embodiments, the method further includes removing the first semiconductor layers to form a gate trench, and forming a gate structure in the gate trench. The gate structure includes a gate dielectric layer wrapped around the second semiconductor layers and a gate electrode layer wrapped around the gate dielectric layer. The gate structure includes a first portion between the upper portions of the gate spacers and a second portion between the lower portions of the gate spacers.

In some embodiments, the insulating layers are between the upper portions of the gate spacers and the gate dielectric layer of the first portion of the gate structure in an X-direction. In some embodiments, the insulating layers are separated from a topmost one of the second semiconductor layers by the second portion of the gate structure in the Z-direction.

In some embodiments, each of the insulating layers has a height in a range from about 1 nm to about 22 nm in the Z-direction. In some embodiments, a distance between each of the insulating layers and a topmost one of the second semiconductor layers in the Z-direction is in a range from about 2 nm to about 23 nm. In some embodiments, a width of the second portion of the gate structure is greater than a width of the first portion of the gate structure.

In some embodiments, the method further includes forming source/drain trenches in the fin structure on opposite sides of the dummy gate structure; forming source/drain features in the source/drain trenches; and forming source/drain contacts over and electrically connected to the source/drain features. The source/drain features are attached to opposite sides of the second semiconductor layers. The insulating layers are sandwiched between the source/drain contacts and a first portion of the gate structure.

In some embodiments, after the partially etching the lower portions of the gate spacers, in an X-direction, a sum of a width of the upper portion of one of the gate spacers and a width of the respective insulating layer is greater than a width of the lower portion of the one of the gate spacers.

In another of the embodiments, discussed is a method of forming a semiconductor structure. The method includes forming a dummy gate structure extending in a Y-direction and over a fin structure; forming gate spacers on sidewalls of the dummy gate structure; removing a portion of the dummy gate structure to form a first trench that exposes upper portions of the gate spacers; and partially etching the upper portions of the gate spacers. The fin structure includes first semiconductor layers and second semiconductor layers alternately stacked in a Z-direction. The method further includes forming insulating layers on sidewalls of the etched upper portions of the gate spacers; removing a remaining portion of the dummy gate structure and the second semiconductor layers to form a gate trench; and forming a gate structure in the gate trench. The gate structure includes a gate dielectric layer wrapped around the second semiconductor layers and a gate electrode layer wrapped around the gate dielectric layer.

In some embodiments, the method further includes after the removing the remaining portion of the dummy gate structure and before the removing the second semiconductor layers, partially etching lower portions of the gate spacers.

In some embodiments, the gate structure includes a first portion between the upper portions of the gate spacers and a second portion between the lower portions of the gate spacers, and the insulating layers are between the upper portions of the gate spacers and the gate dielectric layer of the first portion of the gate structure in an X-direction.

In some embodiments, the insulating layers are separated from a topmost one of the second semiconductor layers by the second portion of the gate structure in the Z-direction.

In some embodiments, after the partially etching the lower portions of the gate spacers, in an X-direction, a sum of a width of the upper portion of one of the gate spacers and a width of the respective insulating layer is greater than a width of the lower portion of the one of the gate spacers.

In some embodiments, after the partially etching the lower portions of the gate spacers, in an X-direction, a width of the upper portion of each of the gate spacers is smaller than a width of the lower portion of each of the gate spacers.

In some embodiments, the forming the insulating layers includes forming an insulating material in the first trench; and removing a horizontal portion of the insulating material from a top surface of the remaining portion of the dummy gate structure, such that a remaining portion of the insulating material layer formed on sidewalls of the etched upper portions of the gate spacers forms the insulating layers.

In yet another of the embodiments, discussed is a semiconductor structure. The semiconductor structure includes a substrate; nanostructures suspended over and vertically arranged over the substrate; a gate structure wrapped around each of the nanostructures, wherein the gate structure includes a gate dielectric layer and a gate electrode layer formed on the gate dielectric layer; gate spacers formed on opposite sides of the gate structure and over a topmost one of the nanostructures; and insulating layers formed on sidewalls of upper portions of the gate spacers. The gate structure includes a first portion between the upper portions of the gate spacers and a second portion between lower portions of the gate spacers. The upper portions of the gate spacers are separated from the first portion of the gate structure by the insulating layers, and the lower portions of the gate spacers are in direct contact with the second portion of the gate structure.

In some embodiments, a width of the second portion of the gate structure is greater than a width of the first portion of the gate structure. In some embodiments, a sum of a width of the upper portion of one of the gate spacers and a width of the respective insulating layer is greater than a width of the lower portion of the one of the gate spacers.

In some embodiments, the semiconductor structure further includes source/drain features attached to opposite sides of the nanostructures, and source/drain contacts formed on the source/drain features. The source/drain contacts are funnel-shaped.

In yet another of the embodiments, discussed is a method of forming a semiconductor structure. The method includes forming a fin structure over a substrate in a Z-direction; forming a dummy gate structure extending in a Y-direction and over the fin structure; and forming gate spacers on sidewalls of the dummy gate structure. The fin structure includes first semiconductor layers and second semiconductor layers alternately stacked. The dummy gate structure includes a dummy gate dielectric layer and a dummy gate electrode layer over the dummy gate dielectric layer. The method further includes removing a portion of the dummy gate electrode layer to expose upper portions of the gate spacers; forming insulating layers on sidewalls of the upper portions of the gate spacers; removing a remaining portion of the dummy gate electrode layer; removing the dummy gate dielectric layer to expose lower portions of the gate spacers; and partially etching the lower portions of the gate spacers.

In some embodiments, the remaining portion of the dummy gate electrode layer has a thickness in a range from about 2 nm to about 23 nm in the Z-direction.

In some embodiments, the method further includes removing the first semiconductor layers to form a gate trench, and forming a gate structure in the gate trench. The gate structure includes a gate dielectric layer wrapped around the second semiconductor layers and a gate electrode layer wrapped around the gate dielectric layer.

In some embodiments, the method further includes forming a gate isolation structure extending in the X-direction to separate the gate structure into a first gate segment and a second segment arranged in the Y-direction.

In some embodiments, the forming the gate isolation structure is prior to the forming the insulating layers, and the insulating layers are further formed on sidewalls of an upper portion of the gate isolation structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a fin structure over a substrate in a Z-direction, wherein the fin structure comprises first semiconductor layers and second semiconductor layers alternately stacked;
forming a dummy gate structure extending in a Y-direction and over the fin structure;
forming gate spacers on sidewalls of the dummy gate structure;
removing a portion of the dummy gate structure to form a first trench that exposes upper portions of the gate spacers;
forming an insulating material in the first trench;
partially removing the insulating material to form insulating layers on sidewalls of the upper portions of the gate spacers;
removing a remaining portion of the dummy gate structure to expose lower portions of the gate spacers; and
partially etching the lower portions of the gate spacers.

2. The method of claim 1, further comprising:
removing the first semiconductor layers to form a gate trench; and
forming a gate structure in the gate trench, wherein the gate structure comprises a gate dielectric layer wrapped around the second semiconductor layers and a gate electrode layer wrapped around the gate dielectric layer, wherein the gate structure comprises a first portion between the upper portions of the gate spacers and a second portion between the lower portions of the gate spacers.

3. The method of claim 2, wherein the insulating layers are between the upper portions of the gate spacers and the gate dielectric layer of the first portion of the gate structure in an X-direction.

4. The method of claim 3, wherein the insulating layers are separated from a topmost one of the second semiconductor layers by the second portion of the gate structure in the Z-direction.

5. The method of claim 3, wherein each of the insulating layers has a height in a range from about 1 nm to about 22 nm in the Z-direction.

6. The method of claim 3, wherein a distance between each of the insulating layers and a topmost one of the second semiconductor layers in the Z-direction is in a range from about 2 nm to about 23 nm.

7. The method of claim 3, wherein in the X-direction, a width of the second portion of the gate structure is greater than a width of the first portion of the gate structure.

8. The method of claim 1, further comprising:
forming source/drain trenches in the fin structure on opposite sides of the dummy gate structure;
forming source/drain features in the source/drain trenches, wherein the source/drain features are attached to opposite sides of the second semiconductor layers; and
forming source/drain contacts over and electrically connected to the source/drain features,
wherein the insulating layers are sandwiched between the source/drain contacts and a first portion of the gate structure.

9. The method of claim 1, wherein after the partially etching the lower portions of the gate spacers, in an X-direction, a sum of a width of the upper portion of one of the gate spacers and a width of the respective insulating layer is greater than a width of the lower portion of the one of the gate spacers.

10. A method of forming a semiconductor structure, comprising:
forming a dummy gate structure extending in a Y-direction and over a fin structure, wherein the fin structure comprises first semiconductor layers and second semiconductor layers alternately stacked in a Z-direction;
forming gate spacers on sidewalls of the dummy gate structure;
removing a portion of the dummy gate structure to form a first trench that exposes upper portions of the gate spacers;
partially etching the upper portions of the gate spacers;
forming insulating layers on sidewalls of the etched upper portions of the gate spacers;
removing a remaining portion of the dummy gate structure and the second semiconductor layers to form a gate trench; and
forming a gate structure in the gate trench, wherein the gate structure comprises a gate dielectric layer wrapped around the second semiconductor layers and a gate electrode layer wrapped around the gate dielectric layer.

11. The method of claim 10, further comprising after the removing the remaining portion of the dummy gate structure and before the removing the second semiconductor layers, partially etching lower portions of the gate spacers.

12. The method of claim 11,
wherein the gate structure comprises a first portion between the upper portions of the gate spacers and a second portion between the lower portions of the gate spacers; and
wherein the insulating layers are between the upper portions of the gate spacers and the gate dielectric layer of the first portion of the gate structure in an X-direction.

13. The method of claim 12, wherein the insulating layers are separated from a topmost one of the second semiconductor layers by the second portion of the gate structure in the Z-direction.

14. The method of claim 11, wherein after the partially etching the lower portions of the gate spacers, in an X-direction, a sum of a width of the upper portion of one of the gate spacers and a width of the respective insulating layer is greater than a width of the lower portion of the one of the gate spacers.

15. The method of claim 11, wherein after the partially etching the lower portions of the gate spacers, in an X-direction, a width of the upper portion of each of the gate spacers is smaller than a width of the lower portion of each of the gate spacers.

16. The method of claim 10, wherein the forming the insulating layers comprises:
forming an insulating material in the first trench; and
removing a horizontal portion of the insulating material from a top surface of the remaining portion of the dummy gate structure, such that a remaining portion of the insulating material layer formed on sidewalls of the etched upper portions of the gate spacers forms the insulating layers.

17. A semiconductor structure, comprising:
a substrate;
nanostructures, suspended over and vertically arranged over the substrate;
a gate structure, wrapped around each of the nanostructures, wherein the gate structure comprises a gate dielectric layer and a gate electrode layer formed on the gate dielectric layer;
gate spacers, formed on opposite sides of the gate structure and over a topmost one of the nanostructures; and
insulating layers, formed on sidewalls of upper portions of the gate spacers,
wherein the gate structure comprises a first portion between the upper portions of the gate spacers and a second portion between lower portions of the gate spacers, and
wherein the upper portions of the gate spacers are separated from the first portion of the gate structure by the insulating layers, and the lower portions of the gate spacers are in direct contact with the second portion of the gate structure.

18. The semiconductor structure of claim 17, wherein a width of the second portion of the gate structure is greater than a width of the first portion of the gate structure.

19. The semiconductor structure of claim 17, wherein a sum of a width of the upper portion of one of the gate spacers and a width of the respective insulating layer is greater than a width of the lower portion of the one of the gate spacers.

20. The semiconductor structure of claim 17, further comprising:
source/drain features, attached to opposite sides of the nanostructures; and
source/drain contacts, formed on the source/drain features, wherein the source/drain contacts are funnel-shaped.
